(19) United States
(12) Patent Application Publication
(10) Pub. No.: US 2025/0390637 A1
(43) Pub. Date: Dec. 25, 2025

(54) RISK-AWARE MODEL RANKING

(71) Applicant: International Business Machines Corporation, Armonk, NY (US)

(72) Inventors: Apoorva Nitsure, Cupertino, CA (US); Youssef Mroueh, New York, NY (US); Mattia Rigotti, Basel (CH); Kristjan Herbert Greenewald, Belmont, MA (US); Brian Michael Belgodere, Fairfield, CT (US); Mikhail Yurochkin, Cambridge, MA (US); Jiri Navratil, Cortlandt Manor, NY (US); Igor Melnyk, White Plains, NY (US); Jarret Ross, Wichita, KS (US)

(21) Appl. No.: 18/753,001

(22) Filed: Jun. 25, 2024

(51) Int. Cl. G06F 30/27

(52) U.S. Cl. CPC G06F 30/27

(57) ABSTRACT

Embodiments of the invention provide a computer-implemented method that includes executing, using a processor system, a risk-aware model evaluation. Executing the risk-aware model evaluation includes the risk-aware model evaluation analyzing a dataset that represents one or more non-risk-aware performance metrics associated with one or more models-under-evaluation. Analyzing the dataset comprises determining a subset of the dataset based at least in part on a determination that the subset satisfies one or more risk severity criteria.

### STATEMENT REGARDING PRIOR DISCLOSURES BY THE INVENTOR OR A JOINT INVENTOR

The following disclosure is submitted under 35 U.S.C. 102 (b)(1)(A):
DISCLOSURE(S): “Risk Aware Benchmarking of Large Language Models,” APOORVA NITSURE, YOUSSEF MROUEH, MATTIA RIGOTTI, KRISTJAN GREENEWALD, BRIAN BELGODERE, MIKHAIL YUROCHKIN, JIRI NAVRATIL, IGOR MELNYK, JERRET ROSS; Jun. 6, 2024, 34 pages.

### BACKGROUND

The present invention relates in general to programmable computers operable to implement and evaluate neural network performance. More specifically, the present invention relates to computing systems, computer-implemented methods, and computer program products that perform a novel risk-aware model assessment & ranking process operable to assess/rank models based on risk-consequence severity assessments of various model performance factors. In some embodiments of the invention, the model is a language model.

In its simplest form, artificial intelligence (AI) is a field that combines computer science and robust datasets to enable problem-solving. AI systems can be implemented as AI models, which are algorithms or computer programs that have been trained on a set of data to recognize certain patterns or make certain decisions without further human intervention. AI encompasses the sub-fields of machine learning and deep learning. Machine learning and deep learning are implemented as neural networks (NNs) having input layers, hidden layers and output layers. Machine learning NNs differ from deep learning NNs in that deep learning has more hidden layers than machine learning.

AI model evaluation technologies have been developed to provide feedback on a model's strengths and weaknesses when functioning in real-world applications. Model evaluations cover a variety of performance factors, including, for example, model toxicity, which evaluates a model's tendency to generate offensive or harmful output.

### SUMMARY

Embodiments of the invention provide a computer-implemented method that includes executing, using a processor system, a risk-aware model evaluation. Executing the risk-aware model evaluation includes the risk-aware model evaluation analyzing a dataset that represents one or more non-risk-aware performance metrics associated with one or more models-under-evaluation. Analyzing the dataset includes determining a subset of the dataset based at least in part on a determination that the subset satisfies one or more risk severity criteria.

Embodiments of the invention further provide a computer-implemented method that includes executing, using a processor system, a risk-aware model evaluation. Executing the risk-aware model evaluation includes the risk-aware model evaluation analyzing a dataset including one or more tail regions of empirical probability distributions produced by random variables. The one or more tail regions of empirical probability distributions produced by random variables represent one or more non-risk-aware performance metrics associated with one or more models-under-evaluation. Analyzing the dataset includes determining a subset of the one or more tail regions of empirical probability distributions produced by random variables based at least in part on a determination that the subset satisfies one or more risk severity criteria.

Embodiments of the invention are also directed to computer systems and computer program products having substantially the same features and functionality as the computer-implemented method described above.

Additional features and advantages are realized through techniques described herein. Other embodiments and aspects are described in detail herein. For a better understanding, refer to the description and to the drawings.

### BRIEF DESCRIPTION OF THE DRAWINGS

The subject matter which is regarded as embodiments is particularly pointed out and distinctly claimed in the claims at the conclusion of the specification. The foregoing and other features and advantages of the embodiments are apparent from the following detailed description taken in conjunction with the accompanying drawings in which:

FIG. 1 depicts an exemplary computing environment operable to implement aspects of the invention;

FIG. 2A depicts a simplified block diagram illustrating a model of a biological neuron operable to be utilized in neural network (NN) architectures in accordance with aspects of the invention;

FIG. 2B depicts a simplified block diagram illustrating a deep learning NN architecture in accordance with aspects of the invention;

FIG. 3 depicts a diagram illustrating a non-limiting example of a dimensionality reduction operation operable to utilize word embeddings in accordance with aspects of the invention;

FIG. 4A depicts a simplified block diagram illustrating a non-limiting example of a transformer NN architecture operable to implement aspects of the invention;

FIG. 4B depicts a simplified block diagram illustrating a non-limiting example of an encoder element of a transformer NN architecture operable to implement aspects of the invention;

FIG. 4C depicts a simplified block diagram illustrating a non-limiting example of a decoder element of a transformer NN architecture operable to implement aspects of the invention;

FIG. 5 depicts a non-limiting example of a probability distribution operable to be utilized in connection with aspects of the invention;

FIG. 6A depicts a non-limiting example of a system operable to implement aspects of the invention;

FIG. 6B depicts a non-limiting example of another system operable to implement aspects of the invention;

FIG. 6C depicts a non-limiting example of how portions of the systems shown in FIGS. 6A and/or 6B can be implemented in accordance with aspects of the invention;

FIG. 7 depicts another non-limiting example of how portions of the systems shown in FIGS. 6A and/or 6B can be implemented in accordance with aspects of the invention;

FIG. 8 depicts a non-limiting example of stochastic dominance functionality operable to implement aspects of the invention;

FIG. 9 depicts a non-limiting example of stochastic dominance functionality operable to implement aspects of the invention;

FIG. 10 depicts a non-limiting example of stochastic dominance functionality operable to implement aspects of the invention;

FIG. 11A depicts a non-limiting example of a flow diagram illustrating a methodology in accordance with aspects of the invention;

FIG. 11B depicts a continuation of the flow diagram depicted in FIG. 11A;

FIG. 12 depicts a non-limiting example of a combination block diagram and flow diagram illustrating methodologies and structures in accordance with aspects of the invention;

FIG. 13 depicts a non-limiting example of a flow diagram illustrating a methodology in accordance with aspects of the invention;

FIG. 14 depicts a non-limiting example of an algorithm operable to implement aspects of the invention; and

FIG. 15 depicts a non-limiting example of an algorithm operable to implement aspects of the invention.

In the accompanying figures and following detailed description of the disclosed embodiments, the various elements illustrated in the figures are provided with three-digit reference numbers. In some instances, the leftmost digits of each reference number correspond to the figure in which its element is first illustrated.

### DETAILED DESCRIPTION

AI models have provided advancements in a range of technical fields. For example, language models (LMs) have demonstrated useful capabilities in language understanding and generation. However, such capabilities typically come with challenges and risks associated with the trustworthiness of model outputs, as well as the alignment of model outputs with human values and ethics. AI model evaluation technologies have been developed to provide feedback on a model's strengths and weaknesses when the model functions in real-world applications.

AI model evaluation technologies implement processes that generate model performance metrics operable to assess a variety of model performance factors, including, for example, model toxicity. In general, model toxicity metrics evaluate a model's tendency to generate offensive or harmful output (e.g., comments that reflect socially unacceptable biases, hallucinating facts that do not actually exist, or offering customers expensive products for unreasonably low prices).

However, model performance metrics (e.g., mean variance, mean win rate, and the like) generated using known AI model evaluation technologies do not reflect or otherwise convey the model performance metric's risk profile. As used herein, a model performance metric's risk profile goes beyond determining the likelihood of possible model outcomes (e.g., 80% likelihood of an acceptable outcome; and 20% likelihood of an unacceptable outcome) to also consider, determine and communicate the severity of the consequences (i.e., the risk) of the possible model outcomes. For example, a model performance metric that does not reflect or otherwise convey the model performance metric's risk profile could communicate that, for performance metric A, Model-1 generates outcomes that are above an acceptable threshold 90% of the time and generates outcomes that are below the acceptable threshold 10% of the time. Similarly, the same model performance metric, which, again, does not reflect or otherwise convey the model performance metric's risk profile, could communicate that, for performance metric A, Model-2 generates outcomes that are above the acceptable threshold 85% of the time and generates outcomes that are below the acceptable threshold 15% of the time. A user could conclude from such a non-risk-aware performance metric analysis that Model-1 will perform better on performance metric A than Model-2. However, if the user is risk averse, the user prefers models that not only performs well on average but also do not exhibit risky tail profiles. Tail risk is the chance of a negative consequences occurring due to a rare event, as predicted by a probability distribution. Rare events are typically present in the tail region(s) of a probability distribution.

Thus, for a risk averse user, it would be beneficial to be able to incorporate some form of risk awareness into the evaluation of model performance metric A that is operable to evaluate various criteria that reflect risk severity. If risk awareness could be incorporated into performance metric A, such a risk aware analysis could convey, for example, that Model-2's 15% below-threshold performance on performance metric A has mild consequence (e.g., a “conversational agent” or chatbot that some customers find annoying), and Model-1's 10% below-threshold performance on performance metric A has severe consequences (e.g., a “conversational agent” or chatbot that sometimes offers to sell to a customer an expensive item such as a first class plane ticket for one (1) dollar). Thus, for a risk averse user, Model-2 would have superior performance on performance metric A over Model-1.

Accordingly, there is a need in the relevant arts for model evaluation technologies that generate risk aware performance metrics, particularly for risk averse users.

Embodiments of the invention provide computing systems, computer-implemented methods, and computer program products that address the problems associated with model performance metrics that do not reflect or otherwise convey the model performance metric's risk profile. More specifically, embodiments of the invention provide computing systems, computer-implemented methods, and computer program products that perform novel risk-aware model assessment & ranking processes operable to assess/rank AI models based on risk-level assessments of various model performance factors. In embodiments of the invention, the risk level assessments evaluate various criteria that reflect not only risk but also risk severity. In embodiments of the invention, the various risk severity criteria can be evaluated based on risk severity scores that can be used to rank model options based on the various risk severity criteria. In some embodiments of the invention, the model is a language model.

The novel risk-aware model assessment & ranking processes disclosed herein utilize a distributional framework to benchmark model performance metrics of AI models with quantified statistical significance. The novel risk-aware model assessment & ranking processes disclosed herein includes a new statistical relative testing approach based at least in part on first and second order stochastic dominance of performance metrics represented as real random variables, along with an optimal transportation assessment approach that computes violation ratios of the stochastic dominance. The novel first and second order stochastic dominance of performance metrics represented as real random variables, along with the optimal transportation assessment technique, work in tandem to bring out statistical evaluations of risk associated with various performance metrics associated with an AI model. In some embodiments of the invention, a set of to-be-evaluated (TBE) AI models is assembled, and a collection or selection of performance metrics is generated for each AI model. The collection of performance metrics for the TBE AI models are compared using the novel risk-aware model assessment & ranking processes to assess the severity level or significance level of the consequences that result from an AI model drifting from instructions and outputting unwanted content (e.g., toxic content).

Embodiments of the invention provide a distributional framework for assessing socio-technical risks of foundation models with quantified statistical significance. Some embodiments of the invention provide a novel model performance evaluation approach based at least in part on first and/or second order stochastic dominance configured and arranged to evaluate the stochastic dominance of real random variables. In some embodiments of the invention, the second order statistics in the disclosed model performance evaluation approach are used to balance risk-consequence severity and utility when choosing between alternative models. Using the disclosed framework, embodiments of the invention provide a risk-aware approach for foundation model selection given guardrails quantified by specified performance metrics. Embodiments of the invention, define a performance metrics collection for each model as a means to aggregate a collection of performance metrics, and perform model selection based on the stochastic dominance of these performance metrics collections. The statistical significance of the disclosed tests is backed theoretically by an asymptotic analysis via central limit theorems instantiated in practice via a bootstrap variance estimate. The disclosed framework can be used to compare various large language models regarding risks related to drifting from instructions and outputting toxic content.

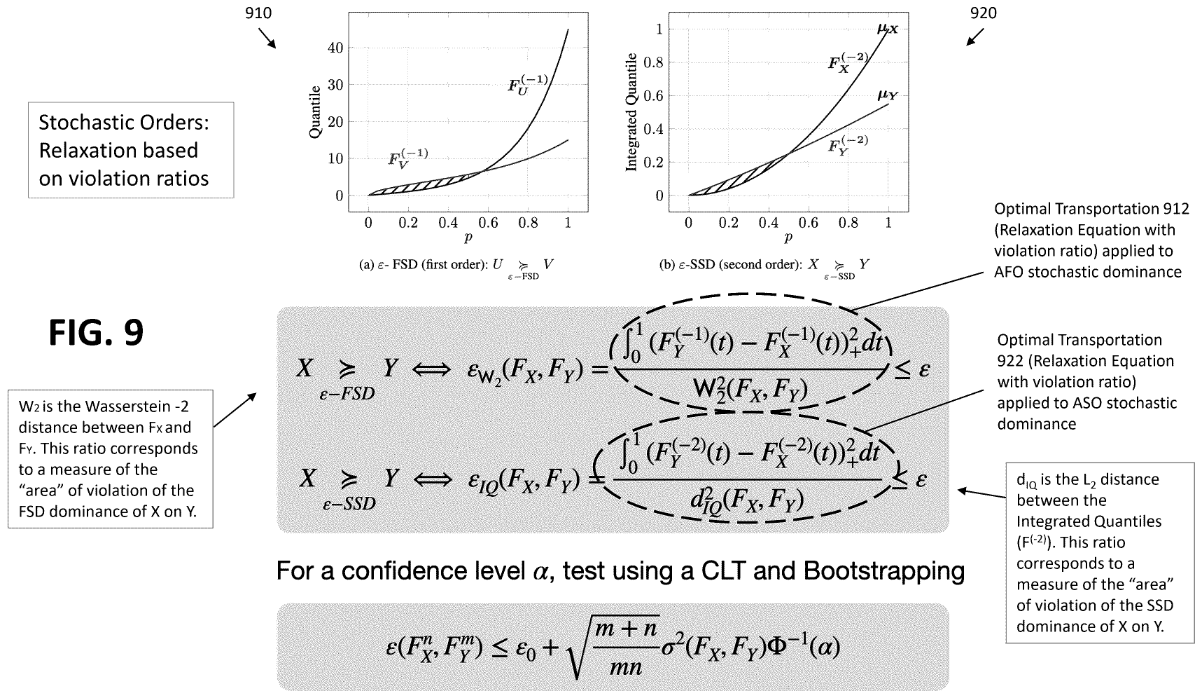

Embodiments of the invention provide technical benefits and technical effects. The disclosed model evaluation framework in accordance with embodiments of the invention provides an interpretable performance-metrics-collection for aggregating performance metrics. The disclosed performance-metrics-collection normalizes and aggregates performance metrics, thereby providing a single interpretable number assessing each output of a LM. A higher value of the performance-metrics-collection is preferable. Additional technical benefits and technical effects of aspects of the invention include the disclosed model evaluation framework configured and arranged to provide risk assessment via second order stochastic dominance. Stochastic orders define partial orders on random variables. Embodiments of the invention utilize stochastic order to compare and/or select LMs based on comparisons of their performance-metrics-collections. A performance-metrics-collection dominates in the first order stochastic dominance (FSD) if the performance-metrics-collection has higher quantiles for all percentiles. However, the quantiles of a performance-metrics-portfolio of an LM don't provide a clear ordering in that one quantile does not dominate throughout (e.g., as shown in FIG. 9). Accordingly, FSD alone does not adequately assess the risks of these models. Embodiments of the invention address this shortcoming in known FSD relationships by using second stochastic dominance (SSD), where one performance-metric-collection dominates another performance-metric-collection if the one performance-metric-collection has higher tail values at risk (TVAR) for all percentiles (also known as Conditional Value at Risk). TVAR represents normalized integrated quantiles, assessing the risks of low values in the performance-metric-collection). Small TVAR corresponds to fat left tails in the distribution of a performance-metric-collection, thereby identifying risky LMs as those with the lowest TVAR.

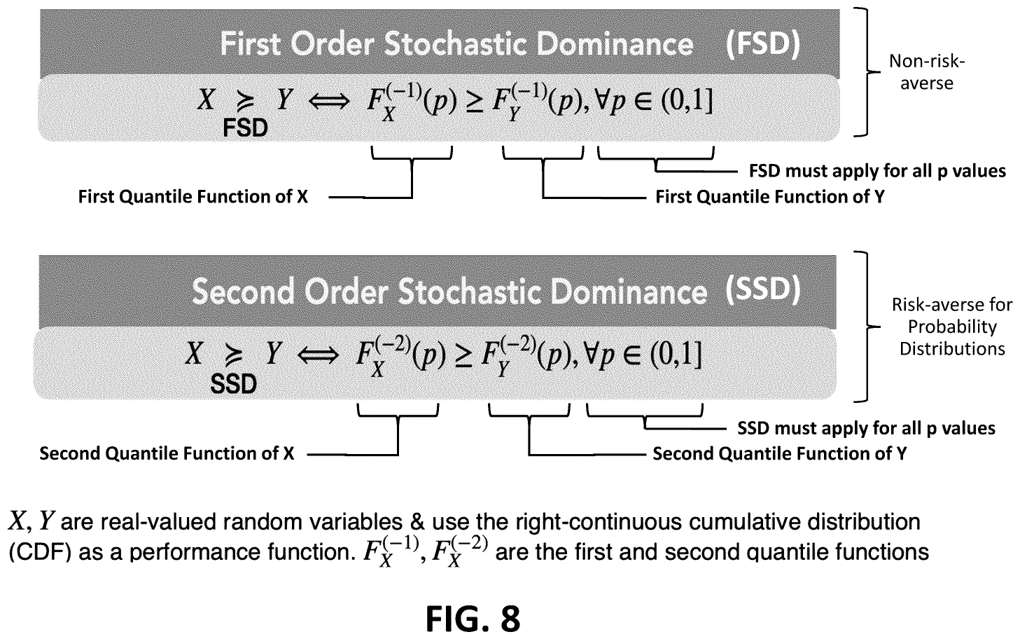

Embodiments of the invention utilize relaxations (e.g., as shown in FIG. 9) of stochastic dominance to allow FSD and/or SSD (e.g., as shown in FIG. 8) to be used in a context where data points (e.g., LM responses to prompts from evaluation of datasets) of a probability distribution are available instead of the full probability distribution. Using FSD and/or SSD (e.g., as shown in FIG. 8) in the finite-sample regime formed of a dataset of evaluation responses, it is hard to test for the necessary dominance relationships as there is a need to show the infinite-sample quantile or second quantile properties hold uniformly over all p ∈ (0, 1]. To address this difficulty, embodiments of the invention introduce the relaxation of stochastic dominance (shown in FIG. 9) to generate an almost stochastic dominance or an approximate stochastic dominance analysis in accordance with embodiments of the invention. Almost FSD (&-FSD) is obtained in accordance with aspects of the invention via the violation ratio of FSD shown in FIG. 9. This violation ratio shown in FIG. 9 corresponds to a measure of the “area” of the violation of the FSD dominance of X on Y. Almost SSD (&-SSD), for ε∈ (0, 1/2), is obtained in accordance with aspects of the invention via the violation ratio of FSD shown in FIG. 9. This violation ratio shown in FIG. 9 corresponds to a measure of the “area” of the violation of the SSD dominance of X on Y.

A shortcomings of almost stochastic dominance is the need to fix a threshold & on the violation ratio. When comparing two random variables, setting a threshold is a viable option. Nevertheless, when one needs to rank multiple variables X1, . . . , Xk (considering all pairwise comparisons), setting a single threshold that would lead to a consistent relative stochastic dominance among the k variables becomes challenging. To alleviate this issue, embodiments of the invention utilize relative similarity and dependence tests that circumvent the need for a threshold via relative pairwise testing.

Additional technical benefits and technical effects of aspects of the invention through achieving statistical significance via dominance tests. Embodiments of the invention define statistics that assess the relative dominance of a model's performance-metric-collection on another. Embodiments of the invention subject these statistics to an asymptotic analysis, proving central limit theorems that provide the foundation for hypothesis testing with false discovery rate control. Stochastic dominance hypothesis tests are performed between all pairs of models. Having adjusted the confidence level of these tests, the pairwise rankings are aggregated to a single rank via rank aggregation techniques, a non-limiting example of which is the Borda Algorithm.

Using the above-described technical benefits and technical effects, as well as others described herein, embodiments of the invention address and overcome the non-risk-aware characteristics of minimum-win-rate (MWR) type performance metrics used in known approaches to LM benchmarking, which, in contrast to embodiments of the invention, do not take into account failure modes of the model.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

Many of the functional units of the systems described in this specification have been labeled as modules. Embodiments of the invention apply to a wide variety of module implementations. For example, a module can be implemented as a hardware circuit including custom VLSI circuits or gate arrays, off-the-shelf semiconductors such as logic chips, transistors, or other discrete components. A module can also be implemented in programmable hardware devices such as field programmable gate arrays, programmable array logic, programmable logic devices or the like. Modules can also be implemented in software for execution by various types of processors. An identified module of executable code can, for instance, include one or more physical or logical blocks of computer instructions which can, for instance, be organized as an object, procedure, or function. Nevertheless, the executables of an identified module need not be physically located together but can include disparate instructions stored in different locations which, when joined logically together, function as the module and achieve the stated purpose for the module.

Many of the functional units of the systems described in this specification have been labeled as models. Embodiments of the invention apply to a wide variety of model implementations. For example, the models described herein can be implemented as machine learning algorithms and natural language processing algorithms configured and arranged to uncover unknown relationships between data/information and generate a model that applies the uncovered relationship to new data/information in order to perform an assigned task of the model.

The components/modules of the systems illustrated herein are depicted separately for ease of illustration and explanation. In embodiments of the invention, the functions performed by the components/modules can be distributed differently than shown without departing from the scope of the various embodiments of the invention describe herein unless it is specifically stated otherwise.

Various aspects of the present invention are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present invention to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present invention, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

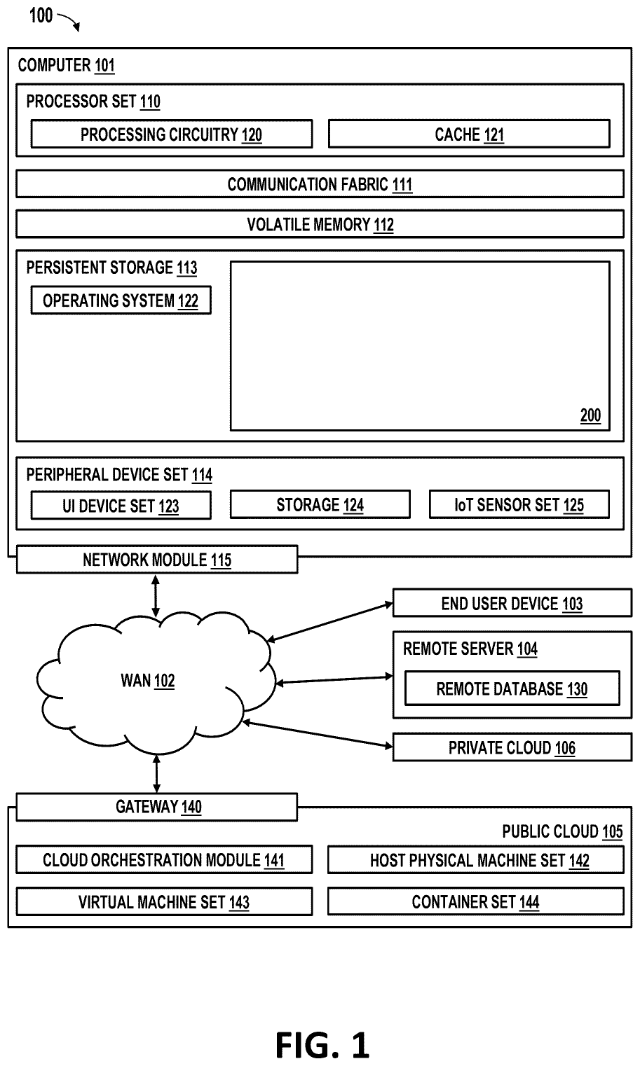

FIG. 1 depicts a computing environment 100 that contains an example of an environment for the execution of at least some of the computer code involved in performing the inventive methods, such as code block 200 operable to implement novel risk-aware model assessment & ranking processes. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Embodiments of the invention can be implemented using various forms of artificial intelligence (AI). In its simplest form, AI is a field that combines computer science and robust datasets to enable problem-solving. AI also encompasses sub-fields of machine learning and deep learning. Machine learning and deep learning are implemented as neural networks (NNs) having input layers, hidden layers and output layers. Machine learning NNs differ from deep learning NNs in that deep learning has more hidden layers than machine learning. AI systems can be implemented as AI algorithms that seek to create expert systems operable to make predictions or classifications based on input data.

Embodiments of the invention are further implemented using natural language processing (NLP), which is a branch of AIthat gives machines the ability to understand natural human speech. Using linguistics, statistics, and machine learning, computers not only derive meaning from what is said or written, they can also understand contextual nuances and a speaker's or writer's intent and sentiment in substantially the same manner as humans.

Embodiment of the invention further leverage deep learning, which has been used extensively for perception tasks in NLP. For example, language models (LMs) can be implemented as transformer-based models that have advanced prediction and classification operations in various natural language tasks such as question answering, summarization, and language (or text) generation. Because the size of LMs can become quite large, they are often referred to as large language models (LLMs).

NNs used to implement aspects of the invention are a specific category of machines that can mimic human cognitive skills. In general, a NN is a network of artificial neurons or nodes inspired by the biological neural networks of the human brain. The artificial neurons/nodes of a NN are organized in layers and typically include input layers, hidden layers and output layers. Machine learning differ from deep learning in that deep learning has more hidden layers than machine learning. Neuromorphic and synaptronic systems, which are also referred to as artificial neural networks (ANNs), are computational systems that permit electronic systems to essentially function in a manner analogous to that of biological brains. Neuromorphic and synaptronic systems do not generally utilize the traditional digital model of manipulating zeros (0s) and ones (1s). Instead, neuromorphic and synaptronic systems create connections between processing elements that are roughly functionally equivalent to neurons of a biological brain. Neuromorphic and synaptronic systems can be implemented using various electronic circuits that are modeled on biological neurons.

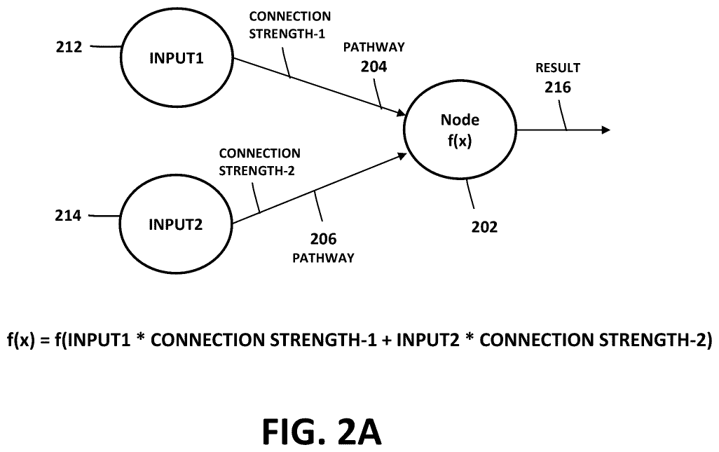

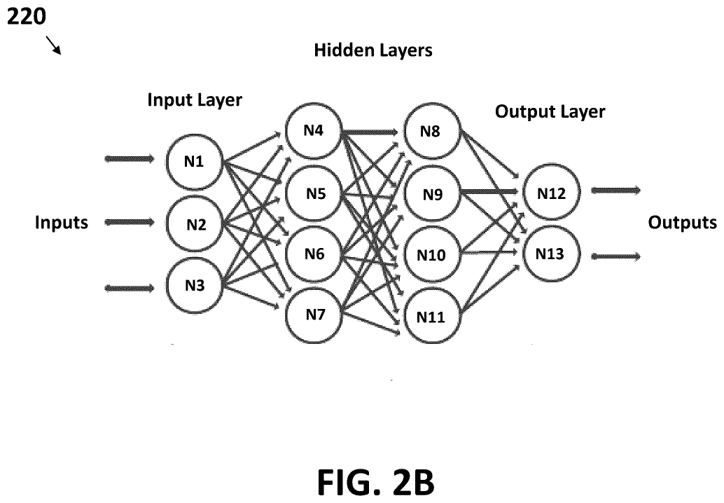

In FIG. 2A, the biological neuron is modeled as a node 202 having a mathematical function, f(x), depicted by the equation shown in FIG. 2A. Node 202 receives electrical signals from inputs 212, 214, multiplies each input 212, 214 by the strength of its respective connection pathway 204, 206, takes a sum of the inputs, passes the sum through a function, f(x), and generates a result 216, which may be a final output or an input to another node, or both. In the present specification, an asterisk (*) is used to represent a multiplication. Weak input signals are multiplied by a very small connection strength number, so the impact of a weak input signal on the function is very low. Similarly, strong input signals are multiplied by a higher connection strength number, so the impact of a strong input signal on the function is larger. The function f(x) is a design choice, and a variety of functions can be used. A suitable design choice for f(x) is the hyperbolic tangent function, which takes the function of the previous sum and outputs a number between minus one and plus one.

FIG. 2B depicts a simplified example of a deep learning NN architecture (or model) 220. In general, NNs can be implemented as a set of algorithms running on a programmable computer (e.g., computer 101 and/or remote server 104 of the computing environment 100 shown in FIG. 1). In some instances, NNs are implemented on an electronic neuromorphic machine (e.g., the IBM®/DARPA SYNAPSE computer chip) that attempts to create connections between processing elements that are substantially the functional equivalent of the synapse connections between brain neurons. In either implementation, NNs incorporate knowledge from a variety of disciplines, including neurophysiology, cognitive science/psychology, physics (statistical mechanics), control theory, computer science, artificial intelligence, statistics/mathematics, pattern recognition, computer vision, parallel processing and hardware (e.g., digital/analog/VLSI/optical). The basic function of a NN is to recognize patterns by interpreting sensory data through a kind of machine perception. Real-world data in its native form (e.g., images, sound, text, or time series data) is converted to a numerical form (e.g., a vector having magnitude and direction) that can be understood and manipulated by a computer. The NN is “trained” by performing multiple iterations of learning-based analysis on the real-world data vectors until patterns (or relationships) contained in the real-world data vectors are uncovered and learned.

NNs use feature extraction techniques to reduce the number of resources required to describe a large set of data. The analysis on complex data can increase in difficulty as the number of variables involved increases. Analyzing a large number of variables generally requires a large amount of memory and computation power. Additionally, having a large number of variables can also cause a classification algorithm to over-fit to training samples and generalize poorly to new samples. Feature extraction is a general term for methods of constructing combinations of the variables in order to work around these problems while still describing the data with sufficient accuracy.

Although the patterns uncovered/learned by a NN can be used to perform a variety of tasks, two of the more common tasks are labeling (or classification) of real-world data and determining the similarity between segments of real-world data. Classification tasks often depend on the use of labeled datasets to train the NN to recognize the correlation between labels and data. This is known as supervised learning. Examples of classification tasks include identifying objects in images (e.g., stop signs, pedestrians, lane markers, etc.), recognizing gestures in video, detecting voices, detecting voices in audio, identifying particular speakers, transcribing speech into text, and the like. Similarity tasks apply similarity techniques and (optionally) confidence levels (CLs) to determine a numerical representation of the similarity between a pair of items.

Returning again to FIG. 2B, the simplified NN architecture/model 220 is organized as a weighted directed graph, where the artificial neurons are nodes (e.g., N1-N13), and where weighted directed edges (i.e., directional arrows) connect the nodes. The NN architecture/model 220 is organized such that nodes N1, N2, N3 are input layer nodes, nodes N4, N5, N6, N7 are first hidden layer nodes, nodes N8, N9, N10, N11 are second hidden layer nodes, and nodes N12, N13 are output layer nodes. Having multiple hidden layers indicates that the NN architecture/model 220 is a deep learning NN architecture/model. Each node is connected to every node in the adjacent layer by connection pathways, which are depicted in FIG. 2B as directional arrows each having its own connection strength. For ease of illustration and explanation, one input layer, two hidden layers, and one output layer are shown in FIG. 2B. However, in practice, multiple input layers, multiple hidden layers, and multiple output layers can be provided. When multiple hidden layers are provided, the NN model 220 can perform unsupervised deep-learning for executing classification/similarity type tasks.

Similar to the functionality of a human brain, each input layer node N1, N2, N3 of the NN 220 receives Inputs directly from a source (not shown) with no connection strength adjustments and no node summations. Each of the input layer nodes N1, N2, N3 applies its own internal f(x). Each of the first hidden layer nodes N4, N5, N6, N7 receives its inputs from all input layer nodes N1, N2, N3 according to the connection strengths associated with the relevant connection pathways. Thus, in first hidden layer node N4, its function is a weighted sum of the functions applied at input layer nodes N1, N2, N3, where the weight is the connection strength of the associated pathway into the first hidden layer node N4. A similar connection strength multiplication and node summation is performed for the remaining first hidden layer nodes N5, N6, N7, the second hidden layer nodes N8, N9, N10, N11, and the output layer nodes N12, N13.

The NN model 220 can be implemented as a feedforward NN or a recurrent NN. A feedforward NN is characterized by the direction of the flow of information between its layers. In a feedforward NN, information flow is unidirectional, which means the information in the model flows in only one direction—forward—from the input nodes, through the hidden nodes (if any) and to the output nodes, without any cycles or loops. In contrast to recurrent NNs, which have a bi-directional information flow, feedforward NNs are trained using the backpropagation method.

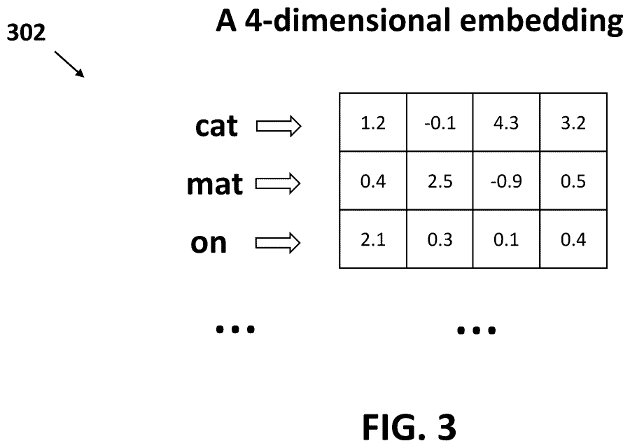

Some embodiments of the invention utilize and leverage embedding spaces. An embedding is a relatively low-dimensional space into which high-dimensional vectors can be translated. Embeddings make it easier to apply machine learning to large inputs like sparse vectors representing words. FIG. 3 illustrates the concept of embedding using an example word embedding 302. In general, NN models take vectors (i.e., an array of numbers) as inputs. Where the inputs are natural language symbols, token/word vectorization refers to techniques that extract information from the natural language symbol corpus and associate to each word of the natural language symbol corpus a vector using a suitable vectorization algorithm that takes into account the word's context.

Word embeddings are typically a low-dimensional dense vector-based space where the semantically similar words are placed closely together. In general, an embedding is a dense vector of floating-point values. In a word embedding, words are represented by dense vectors where a vector represents the projection of the word into a continuous vector space. The dimension of the vector is a parameter that must be specified. However, the values of the embeddings are trainable parameters (i.e., weights learned by the model during training in the same way a model learns weights for a dense layer). More specifically, the position of a word within the vector space of an embedding is learned from text in the relevant language domain and is based on the words that surround the word when it is used. The position of a word in the learned vector space of the word embedding is referred to as its embedding.

FIG. 3 depicts an example diagram of a word embedding 302 in an English language domain. As shown in FIG. 3, each word is represented as a 4-dimensional vector of floating-point values. Another way to think of the word embedding 302 is as a “lookup table.” After the weights have been learned, each word can be encoded by looking up the dense vector it corresponds to in the table. The embedding layer (or lookup table) maps from integer indices (which stand for specific words) to dense vectors (their embeddings). The dimensionality (or width) of the embedding is a parameter that can be selected to match the task for which it is designed. When an embedding layer is created, the weights for the embeddings are randomly initialized (just like any other layer). During training, the weights are gradually adjusted via back-propagation training techniques. Once trained, the learned word embeddings will roughly encode similarities between words (as they were learned for the specific problem on which the model is trained). The general techniques used in word embedding apply to embeddings in other domains, including domains used in embodiments of the invention.

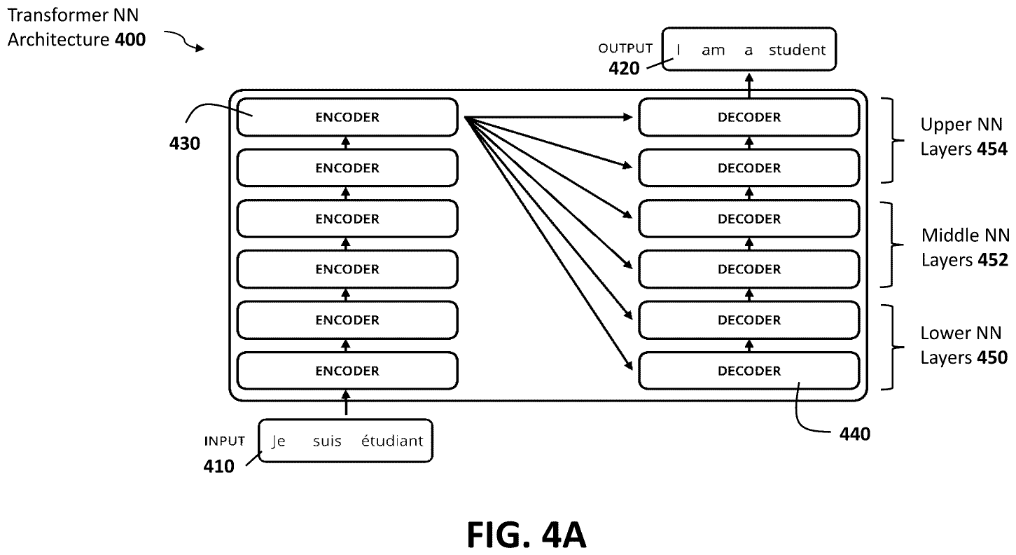

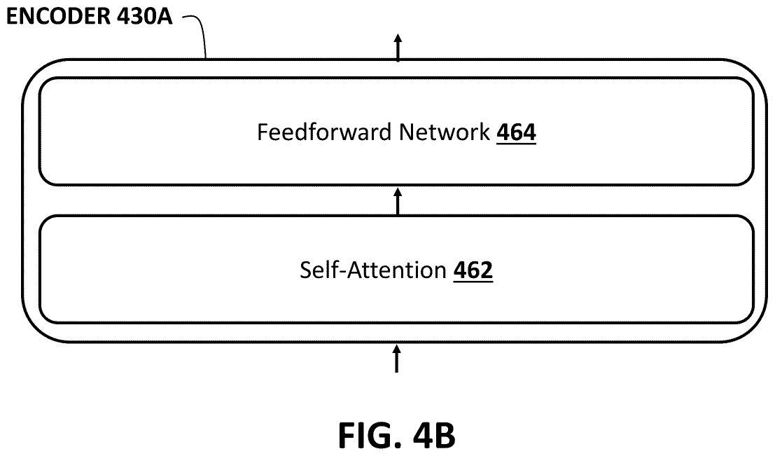

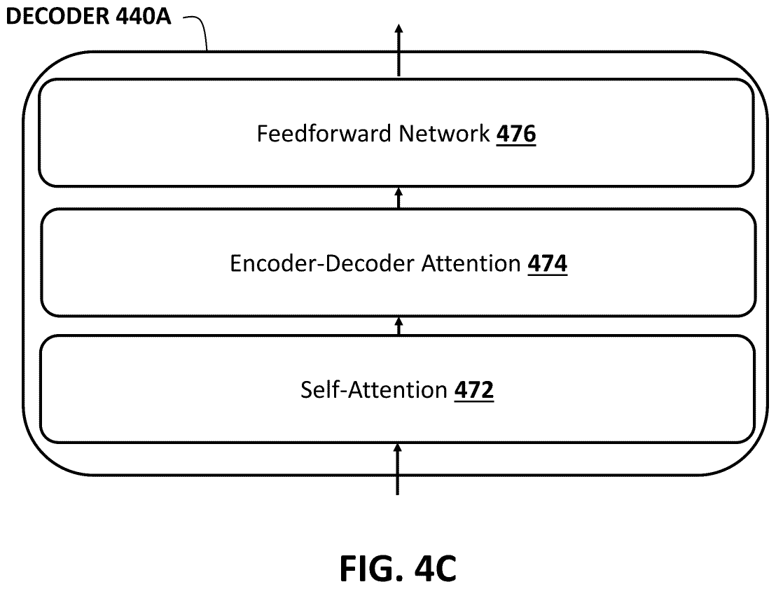

FIGS. 4A, 4B and 4C depict a non-limiting example of various aspects of a transformer NN architecture 400 that can be utilized to implement some aspects of the invention. More specifically, FIG. 4A depicts a simplified block diagram illustrating a non-limiting example of the transformer NN architecture 400; FIG. 4B depicts a simplified block diagram illustrating a non-limiting example of an encoder 430A of the transformer NN architecture 400; and FIG. 4C depicts a simplified block diagram illustrating a non-limiting example of a decoder 440A of the transformer NN architecture 400.

The transformer NN architecture 400 includes tokenization and embedding features. In embodiments of the invention, the transformer NN architecture 400 converts text and other data to vectors and back using tokenization, positional encoding, and embedding layers. Tokenization is the process of splitting a phrase, sentence, paragraph, one or multiple text documents into smaller units. Each of these smaller units is called a token. In general, tokens can be anything, including, for example, a word, a sub-word, or even a character. Multiple types of algorithms are available for performing tokenization. The transformer NN architecture 400 is a sequence-to-sequence NN architecture in which input text is encoded with tokenizers to sequences of integers called input tokens. Input tokens are mapped to sequences of vectors (e.g., word embeddings) via embeddings layers. Output vectors (embeddings) can be classified to a sequence of tokens, and output tokens can then be decoded back to text.

More generally, tokenization is cutting input data into parts (symbols) that can be mapped (embedded) into a vector space. For example, input text is split into frequent words, which is an example of transformer tokenization. Tokenization used in transformer-based NLP models can be sub-word tokenizers. The resulting tokens can be both words or “sub-words” In some instances, special tokens can be appended to the sequence (e.g., class tokens) used for classification embeddings. Positional encodings add token order information. Self-attention and feed-forward layers are symmetrical with respect to the input so positional information is provided about each input token so positional encodings or embeddings are added to token embeddings in transformer encodings. Accordingly, embeddings are learned and/or trained.

As shown in FIG. 4A, the transformer NN architecture 400 includes a series or sequence of encoders 430 and a sequence of decoders 440 configured and arranged as shown. The encoders 430 and decoders 440 are organized around groups of layers including lower NN layers 450, middle NN layers 452, and upper NN layers 454. The transformer NN architecture 400 receives an input 410 (e.g., a sentence in French), uses the encoders 430 and the decoders 440 to perform a task (e.g., translating a French sentence to an English sentence), and, responsive to the input 410 generates an output 420 (e.g., an English translation of a French sentence). More specifically, the encoders 430 are configured and arranged to take the input 410, for example a sentence (i.e., sequences) written in French, and mapping it to high-dimensional representation(s). The encoders 430 are configured to “learn” the parts of the input 410 (i.e., the sequence) that are important and pass them to the high-dimensional representation, and the less-important aspects of the input 410 (e.g., the sequence) are left out. At this stage, the high-dimensional representation cannot be easily understood because there are no semantics involved and the complete mapping has not yet been learned.

The decoders 440 are configured to convert the high-dimensional representation into the output 420, which, in this example, is a sequence (e.g., a sequence written in English). Utilizing the encoders 430 and the decoders 440 allows models to be built that can transduce (i.e., map without losing semantics) “one way” into “another,” e.g., French into English. By training the encoders 430 and the decoders 440 together, a sequence-to-sequence model is created. A sequence-to-sequence model is capable of ingesting (e.g., using data translation processes to convert data/information into a form that is machine-readable) a sequence of a particular kind and outputting another sequence of another kind.

In embodiments of the invention, the transformer NN architecture 400 (also known as a generative language model) can be trained to perform the various tasks described herein. In the transformer NN architecture 400, the encoders 430 can be organized in layers (e.g., lower NN layers 450, middle NN layers 452, and upper NN layers 454) that process the input 410 iteratively one layer after another; and the decoders 440 can also be organized in corresponding layers (e.g., lower NN layers 450, middle NN layers 452, and upper NN layers 454) that do the same thing to the output of the last encoder 430. The function of each encoder 430 in a given layer is to process its input to generate encodings that contain information about which parts of the inputs are relevant to each other. The encoder 430 in one layer passes its set of encodings to the encoder 430 in the next layer as inputs. Each decoder 440 in a corresponding layer does the opposite, taking the output from the last encoder 430 and processing them, using their incorporated contextual information, to generate the output 420. To achieve this, each encoder 430 of a given layer makes use of an attention mechanism (e.g., self-attention 462 shown in FIG. 4B). In the context of NNs, an attention mechanism is a technique that electronically mimics human cognitive attention. The effect enhances the important parts of the input data and fades out the rest such that the NN devotes more computing power on that small but important part of the data. The part of the data that is more important than other parts of the data depends on the context and is learned through training data by gradient descent. Thus, the attention mechanism of the transformer NN architecture 400 weighs the relevance of every other input and draws information from them accordingly to produce the output. Each decoder 440 can include an additional attention mechanism (e.g., self-attention 472 and encoder-decoder attention 474 shown in FIG. 4C) that draws information from the outputs of previous decoders 440 before the current decoder 440 draws information from the encodings. The encoders 430 and the decoders 440 each include a feedforward network (e.g., feedforward network 464 shown in FIG. 4B, and feedforward network 476 shown in FIG. 4C) for additional processing of the outputs, and also contain residual connections and layer normalization steps.

FIG. 4B depicts a simplified block diagram illustrating a non-limiting example of how the encoder 430 (shown in FIG. 4A) can be implemented as the encoder 430A; and FIG. 4C depicts a simplified block diagram illustrating a non-limiting example of how the decoder 440 (shown in FIG. 4A) can be implemented as the decoder 440A. The encoders 430 are very similar to each other, and the decoders 440 are very similar to each other, as well. As shown in FIG. 4B, each encoder 430A includes two sub-layers, namely, a self-attention 462 and a feedforward network 464. The inputs to the encoder 430A first flow through the self-attention 462, which helps the encoder 430A look at other parts of the input 410 as it encodes a specific word. The decoder 440A shown in FIG. 4C has a corresponding self-attention 472 and feedforward network 476 that perform substantially the same functions in the decoder 440A as the self-attention 462 and the feedforward network 464 perform in the encoder 430A. The decoder 440A further includes encoder-decoder attention 474 that helps the decoder 440A focus on relevant parts of the input sentence.

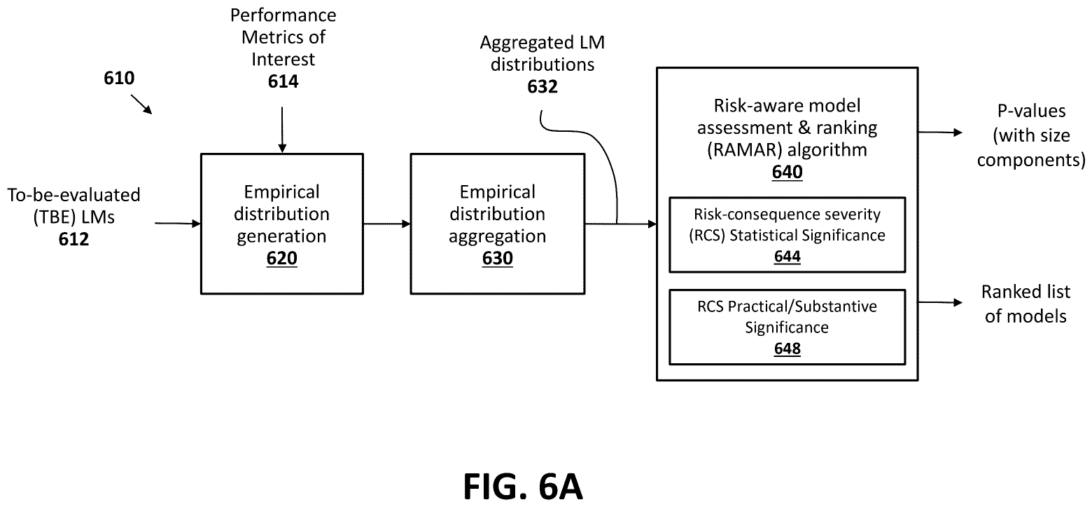

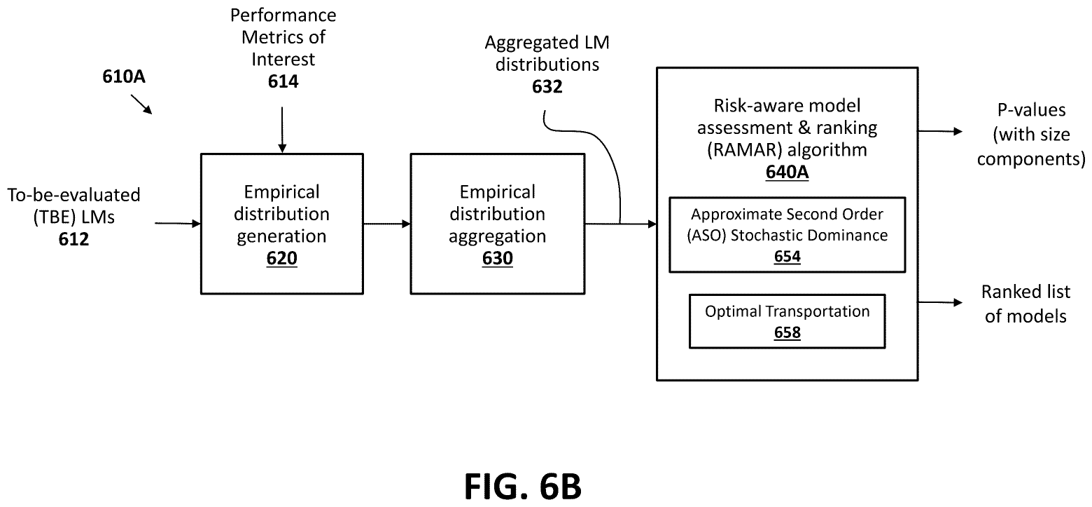

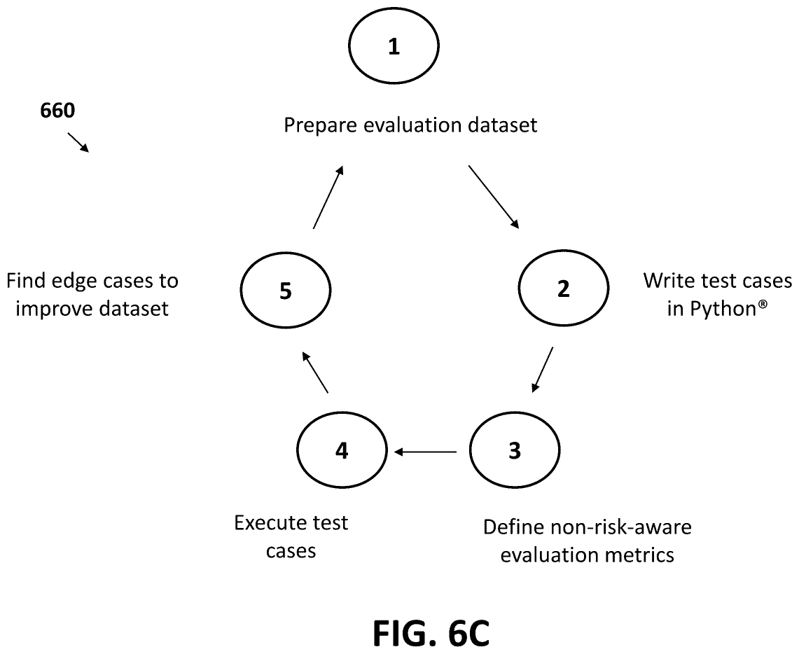

Embodiments of the invention apply the novel risk-aware model assessment & ranking processes disclosed herein (e.g., risk-aware model assessment & ranking algorithms 640, 640A shown in FIGS. 6A and/or 6B) to random variables represented as empirical probability distributions. A random variable is a variable whose value is unknown or a function that assigns values to each of an experiment's outcomes. Random variables are often designated by letters and can be classified as discrete, which are variables that have specific values, or continuous, which are variables that can have any values within a continuous range. Random variables are often used in regression analysis to determine statistical relationships among one another.

Risk analysts use random variables to estimate the probability of an adverse event occurring. In probability and statistics, random variables are used to quantify outcomes of a random occurrence, and therefore, can take on many values. Random variables are required to be measurable and are typically real numbers. For example, the letter X can be designated to represent the sum of the resulting numbers after three dice are rolled. In this case, X could be 3 (1+1+1), 18 (6+6+6), or somewhere between 3 and 18, because the highest number of a die is 6 and the lowest number is 1.

A random variable is different from an algebraic variable. The variable in an algebraic equation is an unknown value that can be calculated. From the equation 10+X=13, the specific value for X can be calculated, which is 3. On the other hand, a random variable has a set of values, and any of those values could be the resulting outcome as seen in the example of the dice above. Random variables can be assigned to properties such as the model performance metrics analyzed in accordance with embodiments of the invention. As described in greater detail subsequently herein, embodiments of the invention assign random variables to model performance metrics to, using aspects of the invention, estimate the severity of consequences that result from an adverse event occurring.

A random variable has a probability distribution that represents the likelihood that any of the possible values of the random variable would occur. For example, if a random variable, Z, is the number on the top face of a die when it is rolled once, the possible values for Z will be 1, 2, 3, 4, 5, and 6. The probability of each of these values is 1/6 as they are all equally likely to be the value of Z. For instance, the probability of Z being 3, or P (Z=3), when a die is thrown is 1/6, and so is the probability of having a 4 or a 2 or any other number on all six faces of a die. Note that the sum of all probabilities is 1.

A random variable can be either discrete or continuous. Discrete random variables take on a countable number of distinct values. For example, where a coin is tossed three times, and if X represents the number of times that the coin comes up heads, then X is a discrete random variable that can only have the values 0, 1, 2, or 3 (from no heads in three successive coin tosses to all heads). No other value is possible for X. Continuous random variables can represent any value within a specified range or interval and can take on an infinite number of possible values. An example of a continuous random variable would be an experiment that involves measuring the amount of rainfall in a city over a year or the average height of a random group of 25 people. Drawing on the latter, if Y represents the random variable for the average height of a random group of 25 people, the resulting outcome is a continuous figure because height can be 5 ft or 5.01 ft or 5.0001 ft. Thus, there is an infinite number of possible values for height.

Random variables produce probability distributions based on experimentation, observation, or some other data-generating process. Thus, random variables allow a variety of events and other phenomena to be evaluated based on a sample of data. Because random variables, whether discrete or continuous, are random with unknown exact values, they enable the assessment and understanding of the probability distribution of those values or the relative likelihood of certain events. As a result, random variables can be used by analysts to test hypotheses and make inferences about events and other phenomena that occur in the natural and social world.

The probability distributions produced by random variables is a statistical function that describes all the possible values and likelihoods that a random variable can take within a given range. This range will be bounded between the minimum and maximum possible values. Precisely where the possible value is likely to be plotted on the probability distribution depends on several factors, including, for example, the distribution's mean (average), standard deviation, skewness, and kurtosis. A common probability distribution is the normal distribution or Gaussian distribution. The data-generating process of the subject phenomenon (e.g., model performance as reflected in model performance metrics) will typically dictate its probability distribution. This process is referred to as the probability density function. Probability distributions can also be used to create cumulative distribution functions (CDFs) that add up the probability of occurrences cumulatively. CDFs always start at zero and end at 100%.

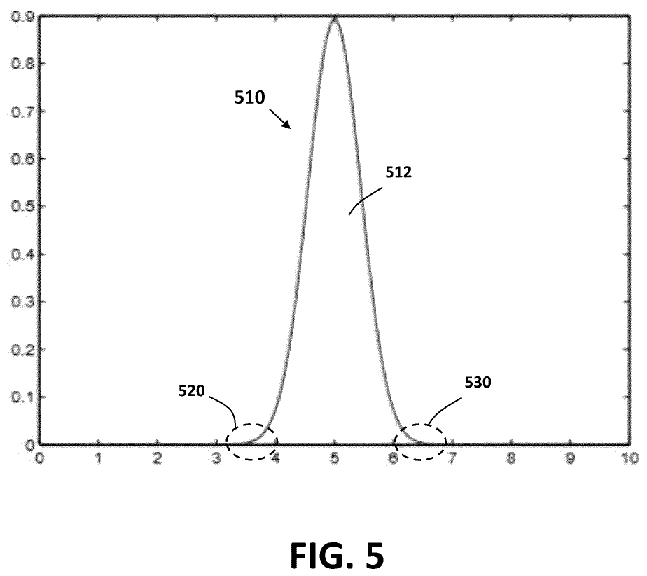

A non-limiting example of a Gaussian distribution 510 is shown in FIG. 5. The Gaussian distribution 510 is a one-dimensional or univariate Gaussian distribution having a two-dimensional (2D) bell shape, and is one of the most common in all of statistics. The “central limit theorem” demonstrates that sums of large numbers of independent, identically distributed random variables are well approximated by a Gaussian distribution. The parameter estimates in a statistical model are also asymptotically Gaussian. Gaussians are widely used in probabilistic modeling for these reasons, together with the fact that Gaussian distributions can be efficiently manipulated using the techniques of linear algebra.

The end portions of a distribution curve are referred to as “tails,” which, for the Gaussian distribution 510, are shown as the trail regions 520, 530. As shown in FIG. 5, for the bell-shaped Gaussian distribution 510, the most probable outcomes are concentrated in a bulge near the center region 512 of the Gaussian distribution 510, which is the average expected outcomes (i.e., the mean), with less probable, more extreme outcomes tapering away toward the edges in the tail regions 520, 530. The tail regions 520, 530 represent the least likely, most extreme outcomes. For risk averse users, the novel risk-aware model assessment & ranking processes disclosed herein (e.g., risk-aware model assessment & ranking algorithms 640, 640A shown in FIGS. 6A and/or 6B) can be focused on the tail regions (e.g., tail regions 520, 530) of the relevant probability distribution(s) (e.g., the Gaussian distribution 510).

Turning now to a more detailed description of aspects of the invention, FIG. 6A depicts a non-limiting example of a computing system 610 operable to implement a novel risk-aware model assessment & ranking processes (e.g., risk-aware model assessment & ranking (RAMAR) algorithm 640) that are operable to assess/rank AI models (e.g., to-be-evaluated (TBE) LMs 612) based on risk-level assessments (e.g., P-values (with size components)) of various model performance factors (e.g., performance metrics of interest 614. As shown, the computing system 610 includes empirical distribution generation functionality 620, empirical distribution aggregation functionality 630, and the novel RAMAR algorithm 640, configured and arranged as shown. The empirical distribution generation functionality 620 and the empirical distribution aggregation functionality 630 rely on empirical distributions rather than complete probability distributions, which are difficult to obtain in practice. An empirical distribution, or an empirical distribution function, can be used to describe a sample of observations of a given variable. The empirical distribution function's value at a given point is equal to the proportion of observations from the sample that are less than or equal to that point. Because the analyses performed by the computing system 610 is based on LM-response samples from a TBE model (e.g., to-be-evaluated (TBE) LMs 612), the empirical distributions analyzed at the empirical distribution generation functionality 620 and the empirical distribution aggregation functionality 630 are based at least in part on the LM-response samples. In some embodiments of the invention, the RAMAR algorithm 640 includes risk-consequence severity (RCS) statistical significance functionality 644 and RCS practical/substantive significance functionality 648.

The computing system 610 is configured and arranged to implement novel model performance evaluation techniques. In embodiments of the invention, some aspects of the computing system 610 (e.g., the functionalities 620, 630) can be performed using known model performance evaluation technologies In machine learning, model performance evaluation uses model monitoring to assess how well a model is performing at the specific task it was designed for. Performance evaluation is the quantitative measure of how well a trained model performs on specific model evaluation metrics in machine learning.

Non-limiting example of model evaluation metrics (or model performance metrics) that are evaluated using known model performance technologies include but are not limited to summarization metrics, answer relevancy metrics, hallucination metrics, knowledge retention metrics, custom metrics, bias metrics, and toxicity metrics. The summarization metric evaluates whether an LM is generating factually correct summaries while including the necessary details from the original text. The answer relevancy metric evaluates how relevant an actual LM output/response is compared to the provided input/prompt. The hallucination metric evaluates whether a LM generates factually correct information by comparing the actual output/response to the provided context. The knowledge retention metric determines whether a LM is able to retain factual information presented throughout a conversation. The custom metric is a user-designed metric that can be generated using custom-metric rules of the particular model performance evaluation technique that is being used. The bias metric evaluates whether a LM output/response contains gender, racial, and/or political bias. The toxicity metric evaluates whether LM outputs/responses meet a standard for so-called toxicity based on a selected definition of the term toxicity. A non-limiting example of a definition for toxicity is outputs/response that meet the standards for reflecting or including personal attacks, mockery, hate, dismissive statements, threats, intimidation, and the like.

In embodiments of the invention, a non-limiting example of how some aspects of the computing system 610 (e.g., the functionalities 620, 630) can be performed is known commercially as “DeepEval.” DeepEval is an open source framework for model-based evaluation to evaluate LM/LLM applications by quantifying their performance on model performance metrics such as faithfulness, answer relevancy, contextual recall, and the like. The “evaluation” performed by DeepEval refers to the process of testing an LM application's outputs/responses, and utilizes test cases, evaluation/performance metrics, and an evaluation dataset (also known as a benchmark dataset).

FIG. 6C depicts a model evaluation workflow 660 that can be implemented using DeepEval. At Step-1 of the model evaluation workflow 660, an evaluation dataset is prepared. The evaluation dataset includes the model responses that are to be evaluated; the input data used to generate the responses; and, optionally, the ground truth response. At Step-2 of the model evaluation workflow 660, test cases are written using, for example, the Python® programming language. A test case is a blueprint provided by DeepEval to unit test LM outputs based on five parameters, namely, inputs; actual output; optionally, expected outputs; optionally, context; and optionally, retrieval context. At Step-3 of the model evaluation workflow 660, evaluation (or model performance) metrics of interest are defined. In contrast to aspects of the invention, the evaluation metrics of the model evaluation workflow 660 are non-risk-aware evaluation metrics that do not assess/rank models based on risk-consequence severity assessments of various model performance factors. Evaluation metrics serve as a standard of measurement for evaluating the performance of a LM's outputs/responses based on a specific criteria of interest. At Step-4 of the model evaluation workflow 660, test cases are executed on the LM being evaluated. At Step-5 of the model evaluation workflow 660, edge cases are identified and used to improve the dataset. Edge cases include unusual model behaviors, exceptional situations, or uncommon scenarios that occur. Edge cases are useful because they involve testing inputs or scenarios that fall beyond the usual operational conditions or just at the boundaries.

Returning to FIG. 6A, the computing system 610 can be implemented to include various features and functionality of the computing environment 100 (shown in FIG. 1), and the functional operations depicted as functionalities 620, 630, 640 can be executed using relevant aspects of the computing environment 100. A set of TBE LMs 612 and performance metrics of interest 614 are selected and assembled for performing thereon a risk aware performance metric analysis in accordance with aspects of the invention. The set of TBE LMs 612 and/or the performance metrics of interest 614 can be selected automatically or manually. The empirical distribution generation functionality 620 of the computing system 610 receives the set of TBE LMs 612, along with the performance metrics of interest 614.

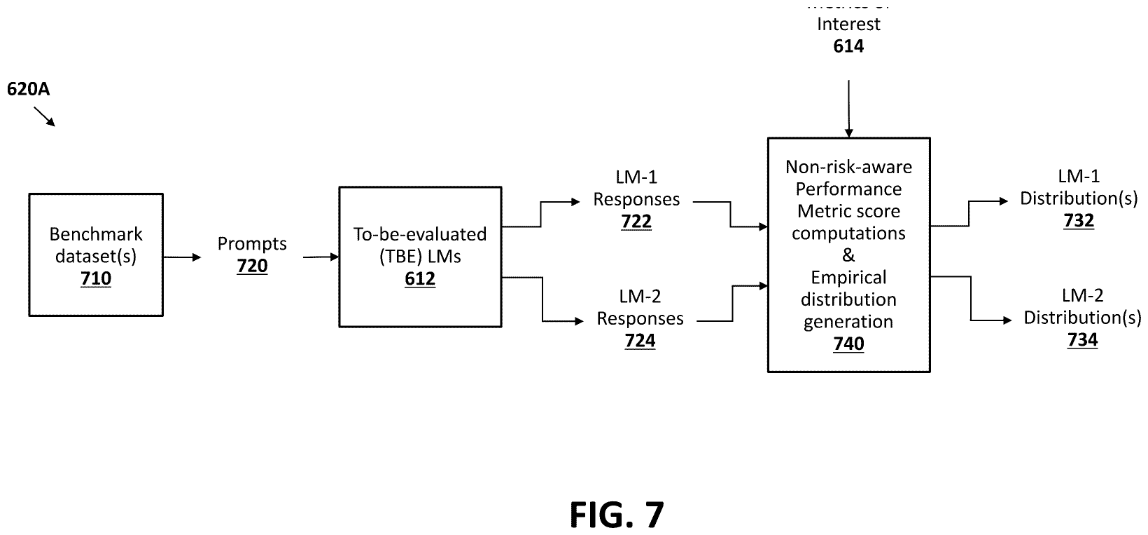

FIG. 7 depicts a non-limiting example of how the operations performed by the empirical distribution generation functionality 620 (shown in FIG. 6A) can be implemented as a methodology 620A. As shown in FIG. 7, the methodology 620A uses or accesses the results of known model evaluation technologies (e.g., the previously-described DeepEval technology) configured and arranged to use one or more benchmark datasets 710 (or evaluation datasets) to apply prompts 720 to the TBE LMs 612 to generate responses from each of the TBE LMs 612. In some embodiments of the invention, the benchmark dataset(s) 710 are associated with one or more performance metrics in that the benchmark dataset(s) 710 are designed to provoke LM responses that facilitate making an assessment of the LM's performance based on the associated performance metric. For ease of illustration and explanation, the example depicted in FIG. 7 illustrates response outputs from two LMs of the TBE LMs 612, which are depicted as LM-1 responses 722 and LM-2 responses 724. It should be understood that, in practice, more than two (2) LMs can be evaluated. The LM-1 responses 722 and the LM-2 responses 724, along with the set of performance metrics of interest 614 are provided to a module configured to implement non-risk-aware performance metric score computations & distribution generation functionality 740.

The non-risk-aware performance metric score computations & distribution generation functionality 740 computes, for each of the performance metrics of interest 614, an associated set of non-risk-aware performance metric score and plots the associated set of non-risk-aware performance metric scores as random variables in an empirical probability distribution. As used herein, the terms “non-risk-aware” identify a performance metric score that does not convey a risk-consequence severity associated with the performance metric score. Accordingly, the non-risk-aware performance metric score computations & distribution generation functionality 740 generates LM-1 distribution(s) 732 and LM-2 distribution(s) 734. In accordance with some embodiments of the invention, the non-risk-aware performance metric score computations & distribution generation functionality 740 generates one LM distribution per performance metric of interest 614 per benchmark dataset 710. For example, one benchmark dataset 710 and one performance metric of interest 614 generates one set of LM response, which generates one LM distribution. As another example, two benchmark datasets 710 and one performance metric of interest 614 generates two sets of LM response, which generates two LM distributions. As another example, two benchmark datasets 710 and two performance metric of interest 614 generate four sets of LM response, which generates four LM distributions.

Continuing with FIG. 7, and also with reference to FIG. 6A, the LM-1 distribution(s) 732 and the LM-2 distribution(s) 734 are provided to the empirical distribution aggregation functionality 630 shown in FIG. 6A. In instances where more than one LM-1 distribution 732 and/or more than one LM-2 distribution 734 are provided, the empirical distribution aggregation functionality 630 aggregates the LM-1 distributions 732 into one aggregated LM-1 distribution 732, and further aggregates the LM-2 distributions 734 into one aggregated LM-2 distribution 734. The aggregated LM-1 distribution 732 and the aggregated LM-2 distribution 734 are depicted in FIG. 6A as the aggregated LM distributions 632, which are provided to the RAMAR algorithm 640. The RAMAR algorithm 640 uses, inter alia, the RCS statistical significance functionality 644 and the RCS practical/substantive significance functionality 648 to generate P-values (with size components) for LM-1 and LM-2 that allow identification of the which of the two models, LM-1 and LM-2, has the highest RCS statistical significance and RCS practical/substantive significance associated with the performance metric that is under evaluation. The RAMAR algorithm 640 further uses, inter alia, the RCS statistical significance functionality 644 and the RCS practical/substantive significance functionality 648 to generate a ranking of the LMs based at least in part on the P-values.

In general, the RAMAR algorithm 640 brings risk awareness into the model performance evaluations performed by the computing system 610 by identifying data points in the aggregated LM distributions 632 that have a meaningful or statistically significant “risk-consequence severity” associated therewith. Due to sensitivity of the environments in which language models are employed, the RAMAR algorithm 640 can be configured and arranged to particularly focus on evaluating risk-consequence severity in tail regions (e.g., tail regions 520, 530 shown in FIG. 5) of the aggregated LM distributions 632 (shown in FIG. 6A).

In some embodiments of the invention, the RAMAR algorithm 640 represents the risk-consequence severity using P-values. Two concepts used to analyze data in statistics are P-values and significance levels. A P-value is a statistical measure that represents the probability of obtaining a result as extreme as, or more extreme than, the one observed, assuming that the null hypothesis is true. In other words, a P-value is a measure of the strength of evidence against the null hypothesis. A P-value of less than 0.05 (or 5%) is often considered statistically significant. A significance level, on the other hand, is a predetermined probability threshold that is used to determine whether a P-value is statistically significant or not. A commonly used significance level is 0.05 (or 5%), however different significance levels can be chosen depending on their research question and the level of evidence required.

Hypothesis testing is a key part of statistical analysis that helps researchers determine whether the results of their study are statistically significant. The process involves setting up a null hypothesis (which states that there is no relationship between the variables being studied) and an alternative hypothesis (which states that there is a relationship between the variables being studied). The researcher then collects data and calculates a p-value. If the p-value is less than the significance level, the null hypothesis is rejected, and the alternative hypothesis is accepted. This means that there is sufficient evidence to support the relationship between the variables being studied.

Statistical significance is a measure of the likelihood that the relationship observed in a study is not due to chance. A result is considered statistically significant if the p-value is less than the significance level. However, statistical significance does not necessarily mean practical/substantive significance. Practical significance refers to the real-world significance of the relationship observed in the study. P-values and significance levels are closely related. The p-value represents the strength of evidence against the null hypothesis, while the significance level represents the level of evidence required to reject the null hypothesis. If the p-value is less than the significance level, the null hypothesis is rejected, and the alternative hypothesis is accepted.

Embodiments of the invention evaluate both statistical significance and practical/substantive significance. A result can be statistically significant, but if the effect size is small or the practical/substantive significance is low, the result may or may not be meaningful in the real world. While statistical significance shows that an effect exists in a study, practical/substantive significance shows that the effect is large enough to be meaningful in the real world. Statistical significance is denoted by p-values whereas practical/substantive significance is represented by effect sizes. Practical/substantive significance means that the sample results deviate strongly (large difference) from the assumed null hypothesis. While statistical significance relates to whether an effect exists, practical/substantive significance refers to the magnitude of the effect. In order to assess practical significance, it would be necessary to also assess the effect size, strength of any relationship (e.g., through a correlation coefficient), and confidence intervals.

FIG. 6B depicts a non-limiting example of a computing system 610A operable to implement aspects of the invention. The computing system 610A is substantially the same as the computing system 610 (shown in FIG. 6A) except the RAMAR algorithm 640 of the computing system 610 is implemented as a RAMAR algorithm 640A having approximate second order stochastic (ASO) dominance functionality 654 and optimal transportation functionality 658. In embodiments of the invention, the optimal transport functionality 614 is operable to compute the violation ratios (e.g., optimal transportation 912 and/or the optimal transportation 922 shown in FIG. 9) given in FIG. 9. In the interest of brevity, the portions of the computing system 610A that are substantially the same as the corresponding portions of the computing system 610 are not repeated here. The ASO dominance functionality 654 implements an ASO dominance ranking method that ranks the aggregated LM distributions 632 from best to worst based on an assessment of the RCS (statistical significance and practical significance) of the aggregated LM distributions 632. In some embodiments of the invention, the ASO dominance functionality 654 can be implemented using ether an absolute testing approach or a relative testing approach. In some embodiments of the invention, the ASO dominance functionality 654 applies pairwise testing to the aggregated LM distributions 632, which are further aggregated using the Borda algorithm to form a ranking (i.e., the ranked list of models depicted in FIG. 6B). The ASO dominance functionality 654 plus bootstrapping can be used to generate the P-value (significance level) for the provided ranking. This indicates to a user the trustworthiness of the rankings. If the trustworthiness is less than required for the relevant evaluation, additional evaluation data can be retrieved and applied to additional iterations of the computing systems 610, 610A to increase confidence.

FIG. 8 depicts a non-limiting example of stochastic dominance functionality operable to implement aspects of the invention. More specifically, embodiments of the invention perform risk aware comparisons between random variable in an empirical probability distribution using risk-consequence severity comparison based on stochastic dominance. FIG. 8 depicts variables and functions associated with first order stochastic dominance (FSD), along with variables and functions associated with second order stochastic dominance. (SSD). As shown in FIG. 8, the random variable X is a metric evaluating the performance of model A on a specific test set. Likewise, the random variable Y represents the evaluation of model B. Thus, X and Y are real-valued random variables and use the right-continuous cumulative distribution function (CDF) as a performance function. In probability theory and statistics, the CDF of a real-valued random variable X, or just distribution function of X, evaluated at x, is the probability that X will take a value less than or equal to x. Every probability distribution supported by real numbers, discrete or “mixed” as well as continuous, is uniquely identified by a right-continuous monotone increasing function. FIG. 8 further depicts the first quantile function of X, the first quantile function of Y, the second quantile function of X, and the second quantile function of Y. In probability and statistics, the quantile function outputs the value of a random variable such that its probability is less than or equal to an input probability value. The quantile function intuitively associates with a range at and below a probability input the likelihood that a random variable is realized in that range for some probability distribution.

Referring still to FIG. 8, where X is one distribution and Y is another distribution, the X distribution first order stochastic dominates the Y distribution, if the first quantile function of X is always bigger than the first quantile function of Y. The minus one (−1) in the superscript of the first quantile function of X identifies that the first quantile function of X is non-risk-averse. As an example, for the first quantile function of X, where p=0.9, the first quantile function of X set for minus one (−1) will return a number that with 0.9 probability X will be smaller than or equal to that number. Thus, if X first order dominates Y, all values of the first quantile function of X will be greater than or equal to all values of the first quantile function of Y. Similarly for SSD, the same general principal applies except the second quantile function of X and the second quantile function of Y have a minus two (−2) superscript, which is referred to as the integrated quantile (or a conditional value at risk or tail value at risk). Thus, the second quantile function of X and the second quantile function of Y having the minus two (−2) superscript allows the SSD to, at least potentially, take into account risk consequences in assessing the probability of various outcomes. For SSD, where it is known that with probability 0.05 some bad event happens. The average probability of the bad event happening below a threshold given by a quantile at p is called the conditional value at risk for a given p.

Although the variables and functions associated with SSD shown in FIG. 8 display the general theoretical characteristic of being risk averse with respect to probability distributions (X or Y) that are known, they are not able to empirically test or estimate SSD and risk aversion using data points sampled from the full probability distributions, which is the type of information that is generally available through model performance evaluation tools (e.g., the empirical distribution generation functionality methodology 620A shown in FIG. 7). FIG. 9 depicts a diagram 910 illustrating “almost first order” (AFO) stochastic dominance, along with a diagram 920 illustrating “almost second order” (ASO) stochastic dominance relationships that occurs in practice. As shown by the diagrams 910, 920 the relevant stochastic dominance condition (e.g., the first quantile function of X is greater than or equal to the first quantile function of Y) is not satisfied in practice throughout the diagrams 910, 920. For example, in diagram 910, the relevant stochastic dominance condition is satisfied above a p value of about 0.6, and the relevant stochastic dominance condition is not satisfied below a p value of about 0.6. Thus, an attempt to obtain results using the theoretical FSD and SSD conditions shown in FIG. 8, which require that the FSD/SSD condition is satisfied for all p-values, would return a “no relationship” response that conveys that neither of the quantile functions for X and Y dominate the other.

In order to implement FSD and/or SSD in a manner that effectively processes data points of a distribution rather than requiring the entire distribution, and also in a manner that always returns a usable answer as to which one of two datasets/distributions dominates the other, embodiments of the invention incorporate a well-behaved optimization approach/function into FSD and/or SSD analyses. A well-behaved function is a function (the optimization approach/function) in a relationship with some other function (e.g., FSD and/or SSD analyses/functions) that is more difficult to analyze. In some embodiments of the invention, the optimization approach is implemented as optimal transportation functionality 912 for providing AFO stochastic dominance, along with optimal transportation functionality 922 for providing ASO stochastic dominance. The optimal transportation functionality 912 and the optimal transportation functionality 922 are well-behaved and allow AFO stochastic dominance and/or ASO stochastic dominance to analyze actual data (e.g., the type of data/information that is generally available through model performance evaluation tools). In the AFO stochastic dominance and/or ASO stochastic dominance equations shown in FIG. 9, epsilon (ε) operates a violation threshold for stochastic dominance. In accordance with embodiments of the invention, epsilon (ε) is measured in terms of an optimal transport distance, which is a concept/tool based on transportation theory. Transportation theory or transport theory is the study of optimal transportation and allocation of resources. Optimal transport is a tool to compare empirical probability distributions. In the context of machine learning and/or signal processing, optimal transport can be used to deal with collections of samples that can be interpreted as probability distributions. Thus, epsilon (ε) is measured in terms of an optimal transport distance, and more specifically in terms of the Wasserstein distance. The Wasserstein distance or Kantorovich-Rubenstein metric is a distance function defined between probability distributions on a given metric space M. If each distribution is viewed as a unit amount of earth (soil) piled on M, the metric is the minimum “cost” of turning one pile into the other, which is assumed to be the amount of earth that needs to be moved times the mean distance it has to be moved. Because of this analogy, the metric is known in computer science as the earth mover's distance. As used in FIG. 9, if X almost stochastically dominates Y for a threshold epsilon (ε), that means that the distribution for X can be moved by epsilon (ε) or less in terms of Wasserstein distance. And if X is so moved, the perturbed version of X would actually second order stochastically dominate Y. FIG. 9 provides violation ratios of stochastic dominance for first and second order that are computed using first and second quantiles and compared to the threshold epsilon for assessment for epsilon (ε) almost stochastic dominance.

Given empirical evaluations of the metrics for two models LM1 and LM2. The violation ratio statistics between LM1 and LM2 can be estimated using the empirical estimates of first and second quantiles. Note that those statistics satisfy a central limit theorem (CLT) that if given infinite number of samples the empirical statistic behaves like a gaussian with the mean being the population statistics and a variance that can be expressed with first or second quantiles. The CLT is crucial for providing statistical significance of the dominance of LM1 on LM2. A bootstrap estimator estimates the variance from empirical observations. For a confidence level a embodiments of the invention compare now the optimal transportation ratio to a modified threshold epsilon that takes into account the variance of the statistics. This procedure is summarized in the equation depicted at the bottom of FIG. 9.

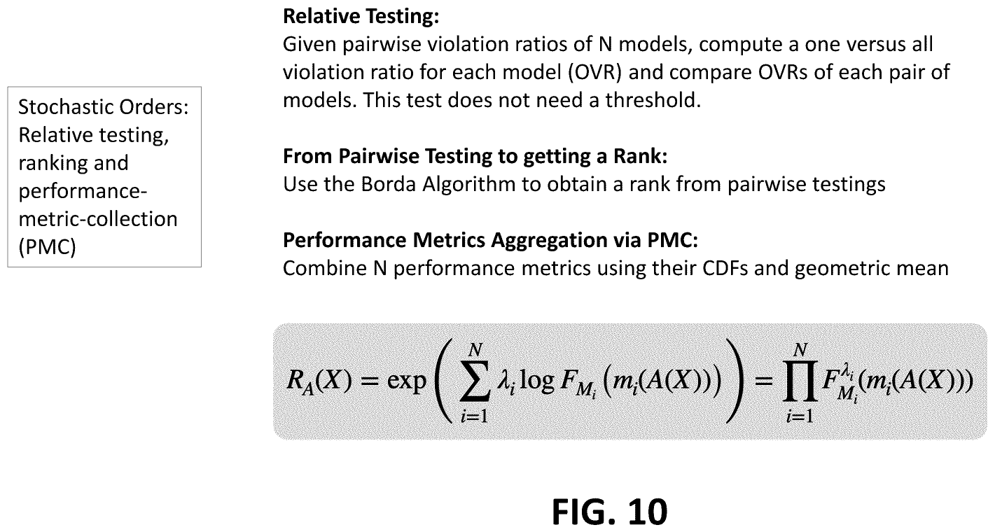

FIG. 10 depicts a non-limiting example of additional stochastic dominance functionality operable to implement aspects of the invention. More specifically, FIG. 10 depicts non-limiting examples of how relative testing, ranking, and ranking performance-metrics-collections are generated using the RAMAR algorithm 640A (shown in FIG. 6B). As shown in FIG. 10, relative testing is performed by taking pairwise violation rations of N models, computing a one versus all violation ratio for each model (OVR), and comparing OVRs of each pair of models. This test does not need a threshold. A Borda algorithm can be used to obtain a rank from pairwise testing. Metrics aggregation via performance-metrics-collections is obtained by combining N metrics using their CDFs and geometric mean using the equation shown in FIG. 10. For the equation shown in FIG. 10, λ=(λ₁, . . . , λ_{N}), which is a probability vector that represents the importance of the mᵢ metrics to the model's end user. Embodiments of the invention capture a model's performance as a collection of performance metrics (performance-metric-collection (PMC)) mᵢ evaluated on a test set D. Embodiments of the invention model this PMC as an Archimedean copula, which forms a weighted geometric mean of the CDFs as reflected by the equation shown in FIG. 10. The equation shown in FIG. 10 normalizes the performance metrics using the CDF of the metric Mᵢ, eliminating the issue of differing dynamic ranges. This CDF can be formed by pooling together the evaluations on all samples and from all models being compared, to ensure that the various RA are comparable. The CDF normalization is monotonic and hence it preserves the order of each performance metric and allows the performance metrics to be aggregated in the probability space the metrics using a simple weighted geometric mean. Computing R_{A}(X) for all test samples X, embodiments of the invention can therefore characterize the distribution of the PMC of the model A. To compare two models it is enough to compare their corresponding PMCs, specifically, Model A is preferred to Model B using ε- or R-SSD. Similar tests can be performed for FSD.

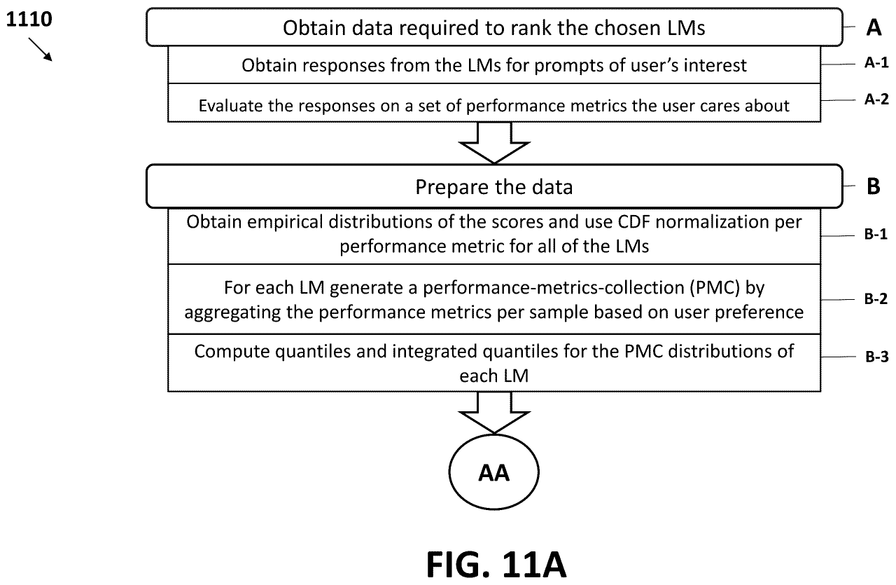

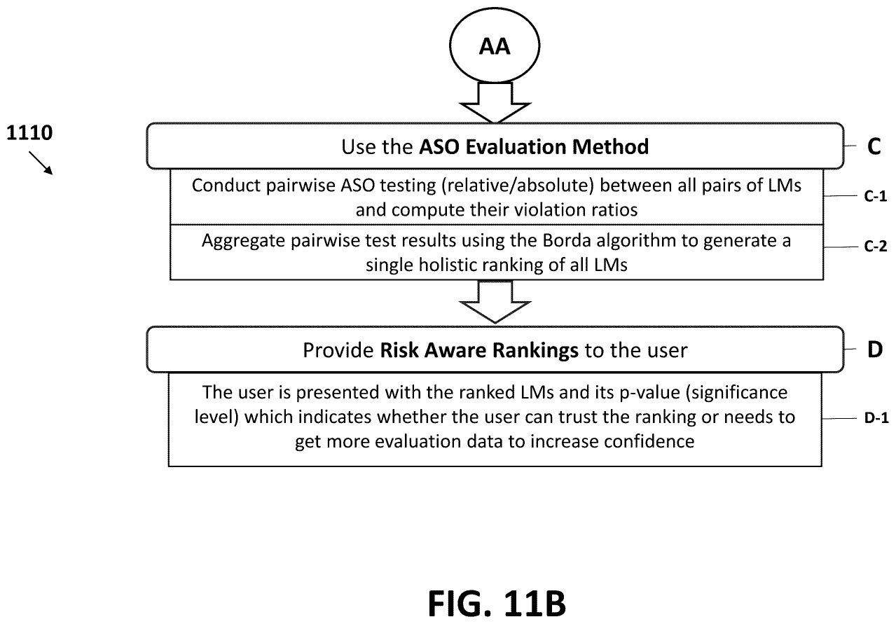

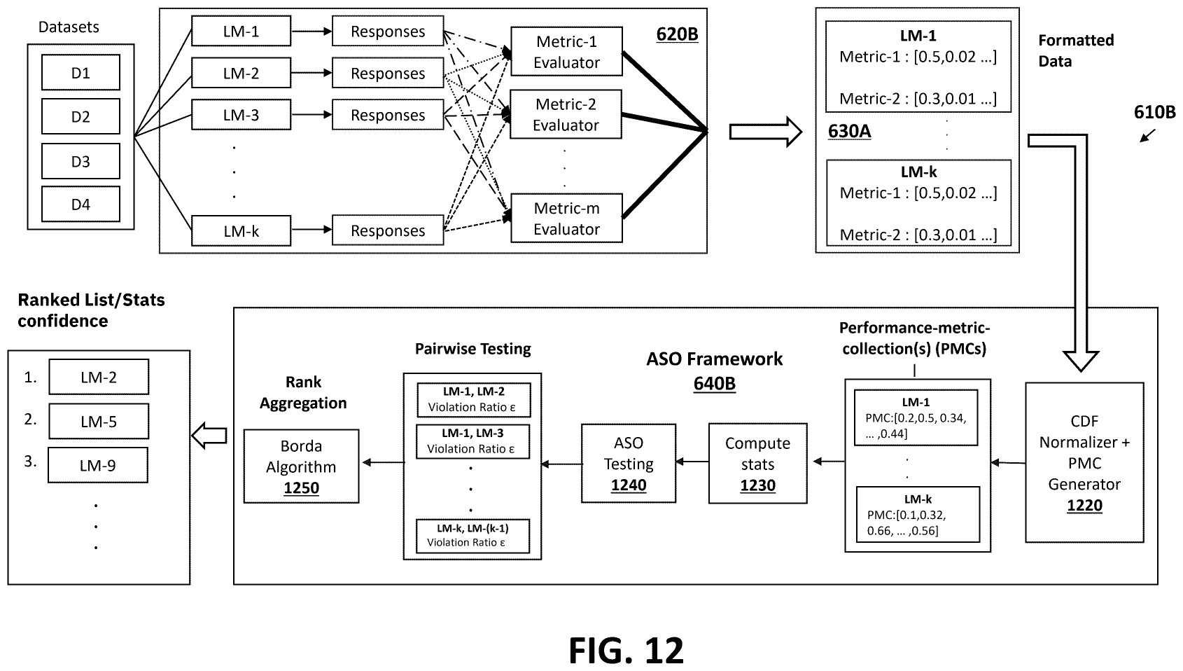

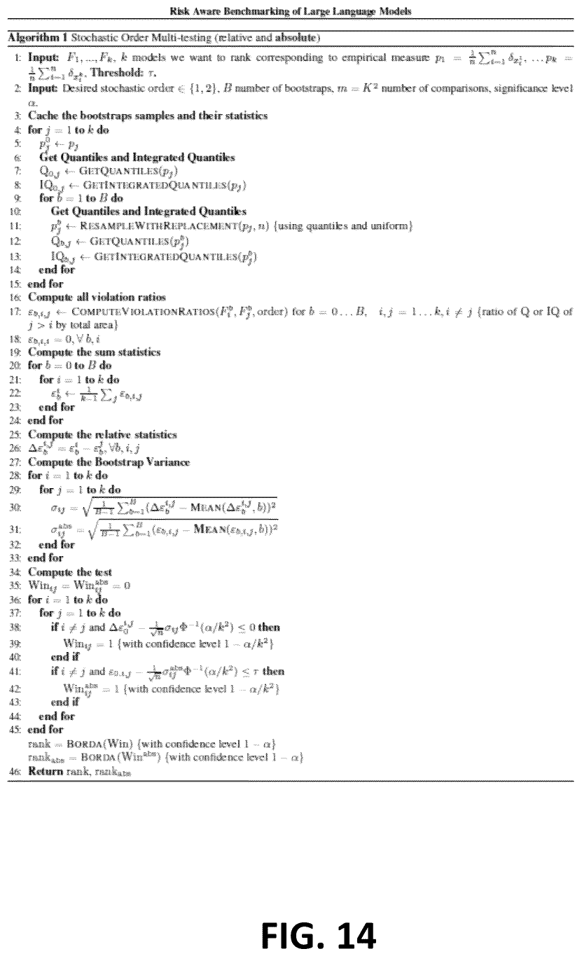

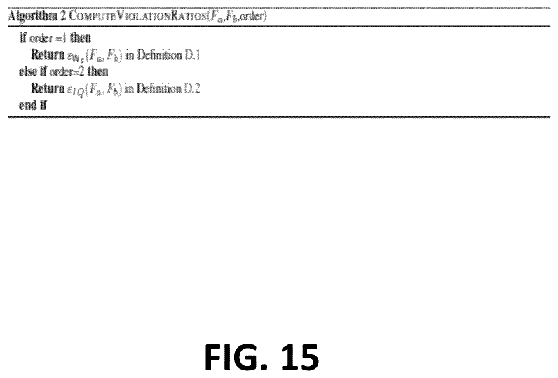

FIG. 12 depicts a non-limiting example of a computing system 610B operable to implement aspects of the invention. The computing system 610B implements aspects of a computer-implemented method represented by the flow diagram 1100 (shown in FIGS. 11A and 11B), and further implements aspects of a computer-implemented method represented by Algorithm 1 and Algorithm 2 (shown in FIG. 14 and FIG. 15, respectively). Algorithm 1 and Algorithm 2 are example computer code implementations of aspects of the invention, which is in a code format that can be read and understood by those skilled in the relevant arts. It should be noted that Algorithm 2 is a routine executed at Line 17 of Algorithm 1. In the following description of computing system 610B, reference will be made, where appropriate, to corresponding elements or blocks of the methodology 1110, along with corresponding lines of Algorithm 1.

Referring now to FIG. 12, the computing system 610B includes empirical distribution functionality implemented by a first module 620B, empirical distribution aggregation functionality implemented by a second module 630A, and ASO stochastic dominance functionality implemented by an ASO framework module 640B, configured and arranged as shown. In operation, Datasets (e.g., D1, D2, D3, D4) are selected to evaluate a set of LMs (e.g., LM-1, LM-2, LM-3, . . . . LM-k, where k=a whole number) based on a set of metrics a user cares about (e.g., performance metrics of interest 614 shown in FIGS. 6A, 6B) (methodology 1110, block A). Module 620B applies the Datasets to the set of LMs as prompts (e.g., prompts 720 depicted in FIG. 7) that generate a corresponding set of Responses (methodology 1110, block A-1), which are all presented to a set of performance metric evaluators (e.g., Metric-1 evaluator, Metric-2 evaluator, . . . . Metric-m evaluator, where m=a whole number). Each metric evaluator evaluates the prompts/responses and outputs an associated score that communicates how the associated LM performed in generating the response (methodology 1110, block A-2). For example, if one of the performance metrics of interest is toxicity, Metric-1 evaluator could be configured to generate a toxicity score for each Response.

In conventional, performance metric systems, the scores or data points for a given performance metric are summed and averaged and presented to communicate information about how the associated LM performed on the given performance metric. Embodiments of the invention provide novel methods of performing deeper analysis of performance metric scores to extract therefrom additional information about the nature of the LM's performance, including specifically the risk severity associated with the performance metric.

The outputs of the Metric Evaluators are provide to module 630A (methodology 1110, blocks B, B-1, B-2, B-3). For example, if each LM generates one thousand (1000) responses, and if 10 performance metrics of interests are evaluated for each LM, a 10×1000 matrix is generated for each LM. Embodiments of the invention aggregate the 10×1000 matrix for each LM into a collection of portfolio of metrics (i.e., a performance-metric-collection (PMC)) for each LM and pass the same to the CDF (cumulative distribution function) normalizer & PMC Generator 1220 (which can be implemented using the equation shown in FIG. 10). The CDF normalizer & PMC Generator 1220 normalizes the various metric formats into a single format and outputs a PMC of normalized performance metrics for each LM. The “compute stats” module 1230 performs pre-ASO computations (Algorithm 1, Lines 3-33) operable to compute quantiles and integrated quantities (e.g., diagram 910 and diagram 912 shown in FIG. 9) for the portfolio distributions of each LM. The ASO module 1240 performs ASO evaluation methods (Algorithm 1, Lines 16-32) (methodology 1110, blocks C, C-1, C-2) applied by conducting pairwise ASO testing (relative/absolute) between all pairs of LMs and violation ratios (e.g., using optimal transportation 912 and optimal transportation 922 shown in FIG. 9) are computed. The pairwise test results are then aggregated using, for example, a Borda algorithm 1250 (Algorithm 1, Lines 45-46) to generate a single holistic ranking of all LMs. The user is the presented with the ranked LMs (e.g., LM-2, LM-5, LM-9) and each LM's associated p-value (significance level), which indicates whether a user can trust the ranking or needs to get more evaluation data and perform more iterations of the methodology 1100 to increase confidence. (methodology 1110, block D-1).

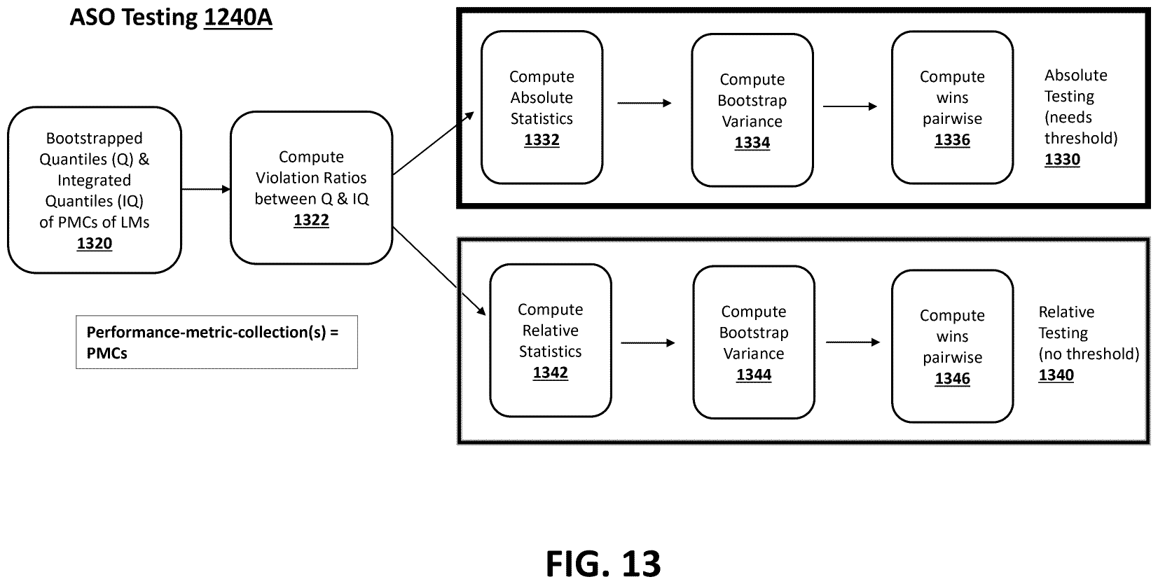

FIG. 13 depicts a non-limiting example of a flow diagram illustrating a non-limiting example of how the ASO testing module 1240 can be implemented using an ASO methodology 1240A in accordance with aspects of the invention. As shown in FIG. 13, block 1320 determines bootstrapped quantities (Q) and integrated quantities IQ of PMCs of the relevant LMs. Block 1322 computes violation ratios between Q and IQ. The ASO methodology 1240A can branch to an absolute testing path 1330 or a relative testing path 1340. In the absolute testing path 1330, block 1332 computes absolute statistics; block 1334 computes bootstrap variance; and block 1336 computes the wins in a pairwise fashion. In the relative testing path 1340, block 1342 computes relative statistics; block 1344 computes bootstrap variance; and block 1346 computes the wins in a pairwise fashion. In operation of the ASO methodology 1240A, given a threshold epsilon, a user can use absolute the ASO methodology 1240A to generate a ranking of the LMs, or a no-threshold ASO relative testing. The procedure starts with computing the bootstrapped quantiles and integrated quantiles of the metrics for each evaluated LLMs (block 1320). This is followed by the computation of the violation ratios for first and second stochastic dominance (block 1322). For the absolute testing path 1330, the statistics formed uses pairwise statistics as a basis, for the relative testing, it uses the one versus all statistics. The statistical significance for both approaches is then obtained via computing the bootstrap variance of each statistic. Each statistic is then compared with the bootstrapped threshold resulting in a pairwise win matrix that can be latter aggregated to a ranking list using the Borda algorithm 1250 (shown in FIG. 12).

Embodiments of the invention depicted herein are not mutually exclusive but instead provide different levels of detail about how aspects of the invention can be implemented in accordance with embodiments of the invention. Persons of skill in the relevant arts will understand that features in one embodiment of the invention can be utilized in features of other embodiments of the invention, and vice versa.

Various embodiments of the invention are described herein with reference to the related drawings. Alternative embodiments of the invention can be devised without departing from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

The terminology used herein is for the purpose of describing particular embodiments of the invention only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

It will be understood that those skilled in the art, both now and in the future, may make various improvements and enhancements which fall within the scope of the claims which follow.

What is claimed is:

1. A computer-implemented method comprising:
executing, using a processor system, a risk-aware model evaluation;
wherein executing the risk-aware model evaluation comprises the risk-aware model evaluation analyzing a dataset that represents one or more non-risk-aware performance metrics associated with one or more models-under-evaluation; and
wherein analyzing the dataset comprises determining a subset of the dataset based at least in part on a determination that the subset satisfies one or more risk severity criteria.

2. The computer-implemented method of claim 1, wherein executing the risk-aware model evaluation further comprises generating a risk severity score based at least in part on the subset.

3. The computer-implemented method of claim 2, wherein:
the one or more models-under-evaluation comprise a first model-under-evaluation and a second model-under-evaluation; and
generating the risk severity score based at least in part on the subset comprises generating a first risk severity score associated with the first model-under-evaluation and generating a second risk severity score associated with the second model-under-evaluation.

4. The computer-implemented method of claim 3, wherein generating the risk severity score based at least in part on the subset further comprises comparing the first risk severity score associated with the first model-under-evaluation to the second risk severity score associated with the second model-under-evaluation using a stochastic dominance evaluation.

5. The computer-implemented method of claim 4, wherein generating the risk severity score based at least in part on the subset further comprises further evaluating a relationship between the first risk severity score associated with the first model-under-evaluation and the second risk severity score associated with the second model-under-evaluation using an optimal transportation analysis.

6. The computer-implemented method of claim 1, wherein:
the dataset comprises a first dataset and a second dataset;
the one or more models-under-evaluation comprises a first model-under-evaluation and a second model-under-evaluation;
the first dataset is associated with the first model-under-evaluation;
the second dataset is associated with the second model-under-evaluation;
the subset comprises a first subset associated with the first dataset and a second subset associated with the second dataset; and
the one or more non-risk-aware performance metrics comprises a first non-risk-aware performance metric.

7. The computer-implemented method of claim 6, wherein the determination that the subset satisfies the one or more risk severity criteria is based at least in part on:
a determination that the first subset satisfies the one or more risk severity criteria; and
a determination that the second subset satisfies the one or more risk severity criteria.

8. The computer-implemented method of claim 7, wherein:
executing the risk-aware model evaluation further comprises generating a risk severity score based at least in part on the subset;
generating the risk severity score based at least in part on the subset further comprises:
generating a first risk severity score associated with the first model-under-evaluation and the first non-risk-aware performance metric;
generating a second risk severity score associated with the second model-under-evaluation and the first non-risk-aware performance metric;
comparing the first risk severity score associated with the first model-under-evaluation to the second risk severity score associated with the second model-under-evaluation using a stochastic dominance evaluation; and
evaluating a relationship between the first risk severity score associated with the first model-under-evaluation and the second risk severity score associated with the second model-under-evaluation using an optimal transportation analysis.

9. A computer system comprising a processor system and a memory electronically coupled to the processor system, wherein the processor system is operable to perform processor system operations comprising:
executing a risk-aware model evaluation;
wherein executing the risk-aware model evaluation comprises the risk-aware model evaluation analyzing a dataset that represents one or more non-risk-aware performance metrics associated with one or more models-under-evaluation; and
wherein analyzing the dataset comprises determining a subset of the dataset based at least in part on a determination that the subset satisfies one or more risk severity criteria.

10. The computer system of claim 9, wherein executing the risk-aware model evaluation further comprises generating a risk severity score based at least in part on the subset.

11. The computer system of claim 10, wherein:
the one or more models-under-evaluation comprise a first model-under-evaluation and a second model-under-evaluation; and
generating the risk severity score based at least in part on the subset comprises generating a first risk severity score associated with the first model-under-evaluation and generating a second risk severity score associated with the second model-under-evaluation.

12. The computer system of claim 11, wherein generating the risk severity score based at least in part on the subset further comprises comparing the first risk severity score associated with the first model-under-evaluation to the second risk severity score associated with the second model-under-evaluation using a stochastic dominance evaluation.

13. The computer system of claim 12, wherein generating the risk severity score based at least in part on the subset further comprises further evaluating a relationship between the first risk severity score associated with the first model-under-evaluation and the second risk severity score associated with the second model-under-evaluation using an optimal transportation analysis.

14. The computer system of claim 9, wherein:
the dataset comprises a first dataset and a second dataset;
the one or more models-under-evaluation comprises a first model-under-evaluation and a second model-under-evaluation;
the first dataset is associated with the first model-under-evaluation;
the second dataset is associated with the second model-under-evaluation;
the subset comprises a first subset associated with the first dataset and a second subset associated with the second dataset; and
the one or more non-risk-aware performance metrics comprises a first non-risk-aware performance metric.

15. The computer system of claim 14, wherein the determination that the subset satisfies the one or more risk severity criteria is based at least in part on:
a determination that the first subset satisfies the one or more risk severity criteria; and
a determination that the second subset satisfies the one or more risk severity criteria.

16. The computer system of claim 15, wherein:
executing the risk-aware model evaluation further comprises generating a risk severity score based at least in part on the subset;
generating the risk severity score based at least in part on the subset further comprises:
generating a first risk severity score associated with the first model-under-evaluation and the first non-risk-aware performance metric;
generating a second risk severity score associated with the second model-under-evaluation and the first non-risk-aware performance metric;
comparing the first risk severity score associated with the first model-under-evaluation to the second risk severity score associated with the second model-under-evaluation using a stochastic dominance evaluation; and
evaluating a relationship between the first risk severity score associated with the first model-under-evaluation and the second risk severity score associated with the second model-under-evaluation using an optimal transportation analysis.

17. A computer program product comprising a computer readable storage medium storing program instructions operable to instruct a processor system to perform processor system operations comprising:
executing a risk-aware model evaluation;
wherein executing the risk-aware model evaluation comprises the risk-aware model evaluation analyzing a dataset that represents one or more non-risk-aware performance metrics associated with one or more models-under-evaluation; and
wherein analyzing the dataset comprises determining a subset of the dataset based at least in part on a determination that the subset satisfies one or more risk severity criteria.

18. The computer program product of claim 17, wherein executing the risk-aware model evaluation further comprises generating a risk severity score based at least in part on the subset.

19. The computer program product of claim 18, wherein:
the one or more models-under-evaluation comprise a first model-under-evaluation and a second model-under-evaluation; and
generating the risk severity score based at least in part on the subset comprises generating a first risk severity score associated with the first model-under-evaluation and generating a second risk severity score associated with the second model-under-evaluation.

20. The computer program product of claim 19, wherein generating the risk severity score based at least in part on the subset further comprises comparing the first risk severity score associated with the first model-under-evaluation to the second risk severity score associated with the second model-under-evaluation using a stochastic dominance evaluation.

21. The computer program product of claim 20, wherein generating the risk severity score based at least in part on the subset further comprises further evaluating a relationship between the first risk severity score associated with the first model-under-evaluation and the second risk severity score associated with the second model-under-evaluation using an optimal transportation analysis.

22. A computer-implemented method comprising:
executing, using a processor system, a risk-aware model evaluation;
wherein executing the risk-aware model evaluation comprises the risk-aware model evaluation analyzing a dataset comprising one or more tail regions of empirical probability distributions produced by random variables;
wherein the one or more tail regions of empirical probability distributions produced by random variables represent one or more non-risk-aware performance metrics associated with one or more models-under-evaluation; and
wherein analyzing the dataset comprises determining a subset of the one or more tail regions of empirical probability distributions produced by random variables based at least in part on a determination that the subset satisfies one or more risk severity criteria.

23. The computer-implemented method of claim 2, wherein:
executing the risk-aware model evaluation further comprises generating a risk severity score based at least in part on the subset;
the one or more models-under-evaluation comprise a first model-under-evaluation and a second model-under-evaluation;
generating the risk severity score based at least in part on the subset comprises generating a first risk severity score associated with the first model-under-evaluation and generating a second risk severity score associated with the second model-under-evaluation;
generating the risk severity score based at least in part on the subset further comprises comparing the first risk severity score associated with the first model-under-evaluation to the second risk severity score associated with the second model-under-evaluation using a stochastic dominance evaluation; and
generating the risk severity score based at least in part on the subset further comprises further evaluating a relationship between the first risk severity score associated with the first model-under-evaluation and the second risk severity score associated with the second model-under-evaluation using an optimal transportation analysis.

24. A computer system comprising a processor system and a memory electronically coupled to the processor system, wherein the processor system is operable to perform processor system operations comprising:
executing a risk-aware model evaluation;
wherein executing the risk-aware model evaluation comprises the risk-aware model evaluation analyzing a dataset comprising one or more tail regions of empirical probability distributions produced by random variables;
wherein the one or more tail regions of empirical probability distributions produced by random variables represent one or more non-risk-aware performance metrics associated with one or more models-under-evaluation; and
wherein analyzing the dataset comprises determining a subset of the one or more tail regions of empirical probability distributions produced by random variables based at least in part on a determination that the subset satisfies one or more risk severity criteria.

25. The computer system of claim 24, wherein:
executing the risk-aware model evaluation further comprises generating a risk severity score based at least in part on the subset;
the one or more models-under-evaluation comprise a first model-under-evaluation and a second model-under-evaluation;
generating the risk severity score based at least in part on the subset comprises generating a first risk severity score associated with the first model-under-evaluation and generating a second risk severity score associated with the second model-under-evaluation;
generating the risk severity score based at least in part on the subset further comprises comparing the first risk severity score associated with the first model-under-evaluation to the second risk severity score associated with the second model-under-evaluation using a stochastic dominance evaluation; and
generating the risk severity score based at least in part on the subset further comprises further evaluating a relationship between the first risk severity score associated with the first model-under-evaluation and the second risk severity score associated with the second model-under-evaluation using an optimal transportation analysis.
